(19) United States
(12) Patent Application Publication
(10) Pub. No.: US 2022/0299390 A1
(43) Pub. Date: Sep. 22, 2022

(54) OPTOELECTRONIC COUPLING PLATFORMS AND SENSORS

(71) Applicant: GRIFFITH UNIVERSITY, Nathan, Queensland (AU)

(72) Inventors: Dzung DAO, Nathan, Queensland (AU); Toan DINH, Nathan, Queensland (AU)

(73) Assignee: GRIFFITH UNIVERSITY, Nathan, Queensland (AU)

(21) Appl. No.: 17/618,106

(22) PCT Filed: Jun. 15, 2020
(86) PCT No.: PCT/AU2020/050602

§ 371 Date: Dec. 10, 2021

(30) Foreign Application Priority Data
Jun. 13, 2019 (NL) 2023306

(51) Int. Cl. G01L 9/00; G01L 19/00; H01L 31/08

(52) U.S. Cl. CPC G01L 9/0052; G01L 19/0092; H01L 31/08

(57) ABSTRACT

A sensing platform comprises a semiconductor junction, in particular a SiC/Si heterojunction, with a pair of electrodes located on a surface of an upper layer of the semiconductor junction in a spaced apart relationship. The sensing platform comprises a light source above the surface of the upper layer to illuminate a part of the surface of the semiconductor junction comprising at least part of one of the electrodes to create a lateral potential gradient between the pair of electrodes through the photovoltaic effect in the semiconductor. Parameters, such as force and temperature, are detected based on measuring a change in electrical resistance of the semiconductor material due to the piezoresistive effect and/or the thermoresistive effect. An external potential difference can be applied between the pair of electrodes to create a tuning current to modulate the piezoresistive and thermoresistive effects in the semiconductor junction. The sensing platform is used for highly sensitive force sensors and highly sensitive temperature sensors.

### FIELD OF THE INVENTION

The present invention relates to optoelectronic platforms and sensors. More particularly, the present invention relates to optoelectronic and optothermotronic semiconductor platforms, methods of production of such platforms and sensors based thereon. In particular, but not exclusively, the present invention relates to sensing platforms based on silicon carbide/silicon semiconductor junctions for mechanical and thermal sensors.

### BACKGROUND TO THE INVENTION

Sensors and sensor modules are employed in just about every aspect of life including telecommunications, household appliances, building construction, automation, building controls, transportation, energy and water distribution and control, security, materials production and IT to name a small cross-section of such applications. There is a continual drive to miniaturise such sensors and improve their sensitivity and reliability.

The piezoresistive effect has been utilized as a major mechanical sensing technology. Piezoresistive sensitivity refers to the fractional change of resistance in response to applied strain, known as gauge factor (GF). This sensing technology can be found in a wide range of applications such as strain, force, pressure and tactile sensors, as well as accelerometers. The advantages of this sensing concept include, but are not limited to low power consumption, simple readout circuits and capability of miniaturisation. However, the performance of the piezoresistive effect depends upon the carrier mobility, which is fundamentally limited by the nature of the piezoresistive materials.

Enhancement of the piezoresistive effect has been of high interest in developing ultra-sensitive sensing devices. The conventional strategy focuses on the arrangement of piezoresistors in optimal crystal orientations. For example, the longitudinal piezoresistive coefficient of p-type Si (100) is approximately 6.6×10⁻¹¹ Pa⁻¹ in the [100] direction, while its value increases to 71.8×10⁻¹¹ Pa⁻¹ in the [110] direction. GF of single crystalline p-type 3C—SiC is 5.0 and 30.3 in the [100] and [110] orientations, respectively. A significant improvement of piezoresistive sensitivity has also been demonstrated using optimal doping concentrations.

In terms of material choice, metal strain gauges have been commercialized and widely employed in industries, research and daily life. However, the piezoresistive effect in metals is fundamentally based on the geometry change under applied strain, resulting in a low GF typically less than 2. Semiconductors such as silicon (Si) and silicon carbide (SiC) have emerged as suitable materials for strain sensing, owing to their relatively high GF of up to 200 in Si and 30 in SiC. While the strain-induced geometry change can be neglected in these semiconductors, the carrier mobility governs the piezoresistive performance.

Interestingly, significant enhancement of piezoresistive effect can be achieved by scaling down piezoresistors to a nanometre scale, owing to the advanced nanofabrication techniques. At the nanometre scale, the charge mobility and surface-to-volume ratio considerably increase, resulting in the significant improvement of the strain sensitivity. For instance, a giant piezoresistive effect in top-down fabricated silicon nanowires (SiNWs) have been observed with a longitudinal piezoresistive coefficient of up to −3550×10⁻¹¹ Pa⁻¹ which is almost 38 times higher than bulk Si. 13 However, reliability of the giant piezoresistive effect in nanoscales is still controversial.

More recently, coupling the piezoresistive effect with other physical effects, such as piezoelectricity, has emerged as an advanced and promising approach to boost piezoresistivity. As such, the strain-modulated electric potential in piezoelectric materials, known as piezotronics, can be used to control/tune the transport of charge carriers. By utilizing strain-induced piezoelectric polarisation charges at a local junction of ZnO nanowires to modify its energy band structures, an increase of GF from 300 to 1,250 has been demonstrated when the strain increases from 0.2% to 1%. Additionally, an electrically controlled giant piezoresistive effect in SiNWs has been reported with a GF of up to 5,000, employing electrical bias to manipulate the charge carrier concentration.

Coupling of multiple physical effects in nanostructures has also been employed to modulate the electrical transport in logic circuits, enhance sensitivity and detection resolution of bio/chemical sensors, and improve photovoltaic performance of solar cells. An enhancement up to 76% of output voltage has been revealed in solar cells by modulating the interfacial charge transfer in InP/ZnO heterojunctions under applied temperature gradients across the device.

The detection and mediation of temperature is also of considerable interest in industrial processes, laboratory applications and in daily life activities. Over the past century, tremendous progress has been made in the development and commercialisation of temperature sensing devices including resistive temperature detectors (RTD) and thermistors. These devices employ the electrical resistance change versus temperature variation to define the temperature coefficient of resistance (TCR) as an indicator for the temperature sensitivity. TCR-based temperature sensing devices including resistive temperature detectors (RTD) became popular, owing to their simplicity in design, fabrication and implementation. Currently, RTD sensors are one of the main products of the current temperature sensing market.

Nevertheless, these sensing technologies are fundamentally based on lattice scattering phenomena and/or thermal excitation of charge carriers, which limit the sensing performance, e.g. TCR is typically lower than 0.5%/K. The development of advanced sensing technologies, which can significantly enhance the sensing performance of conventional solid-state devices by manipulating the generation and transport of charge carriers, is desirable for a wide range of thermal sensing applications. Several strategies have been proposed to enhance the temperature sensitivity (e.g. TCR) of conventional sensing materials and solid-state electronic devices. For example, the modification of surface roughness in p-type silicon (p-Si) with gold nanoparticles (Au-NPs) can increase the temperature sensitivity up to 100%. This sensing concept could be suitable for electronic applications in liquid-helium and cryogenic temperatures (e.g. 10-30K). In nanocomposites, the alternation of tunneling distance between conductive nanotubes by volume-phase-transition could cause a large TCR value at elevated temperatures. At a volume phase transition temperature (VPTT) where the volume significantly increases, electrons require a higher energy to pass through the barrier, resulting in a significant decrease in electrical conductivity. Nevertheless, volume expansions or phase changes are limited at a specific temperature and certain conditions, posing great challenges for practical sensing applications. Currently, generation and modulation of the thermally excited charge carriers have faced great challenges. For instance, thermal excitation occurs at near room temperature, while the doping concentration of charge carriers limits the excitation rate as well as the sensing performance of solid-sate electronics. Therefore, the temperature sensitivity of thermal devices is typically limited at 0.7%/K.

### OBJECT OF THE INVENTION

It is a preferred object of the present invention to provide a sensing platform and sensors based thereon that address or at least ameliorate one or more of the aforementioned problems of the prior art and/or provides a useful commercial alternative.

### SUMMARY OF THE INVENTION

Generally, embodiments of the present invention are directed to sensing platforms comprising semiconductor junctions, methods of forming such sensing platforms and sensors based on such platforms. The semiconductor junctions comprise a pair of spaced apart surface electrodes which are unevenly or asymmetrically illuminated by a light source to create a lateral potential gradient between the pair of electrodes through the photovoltaic effect in the semiconductor material. Such semiconductor junctions provide a platform for a range of sensors with significantly enhanced sensitivity compared with known sensors based on a large change in the lateral potential gradient resulting from the generation and repopulation of charge carriers (holes and electrons) under light illumination and the electric field modulation of carrier energy. The semiconductor junction forms a diode to allow the charge carriers to travel in only one direction from a substrate to a top layer of the semiconductor junction. Some embodiments of the sensing platform include detecting force, such as strain, wherein strain-induced energy band shifts of charge carriers in the semiconductor material result in a change in carrier mobility and electrical resistivity. Some embodiments of the sensing platform include detecting temperature, wherein the application of thermal energy generates charge carriers, leading to a change in carrier concentration, mobility and electrical resistivity. Embodiments of the present invention will be described with reference to pressure sensors and temperature sensors, but the present invention can also be embodied in other types of sensors, including mechanical sensors such as, but not limited to, flow sensors, force sensors, inertia sensors and tactile sensors.

According to one aspect, but not necessarily the broadest aspect, the present invention resides in a sensing platform comprising:

a semiconductor junction;

a pair of electrodes located on a surface of an upper layer of the semiconductor junction in a spaced apart relationship; and

a light source to illuminate a part of the surface of the semiconductor junction comprising at least part of one of the electrodes to create a lateral potential gradient between the pair of electrodes through the photovoltaic effect in the semiconductor;

wherein at least one parameter is detected based on measuring a change in electrical resistance of the semiconductor material due to the piezoresistive effect and/or the thermoresistive effect.

In preferred embodiments, the semiconductor junction is in the form of a heterojunction comprising the upper layer on a substrate. In preferred embodiments, the upper layer is in the form of a nanofilm that allows the light to pass through and the substrate absorbs the light and generates electron-hole pairs. Examples of materials for the substrate include, but are not limited to small bandgap materials, such as silicon and germanium.

In a preferred embodiment, the semiconductor junction comprises a SiC/Si heterojunction. However, it is envisaged that in other embodiments, other materials and material combinations which possess a photovoltaic effect and a piezoresistive effect and/or thermoresistive effect can be used. Examples of such materials include, but are not limited to semiconductor materials, such as GaAs, GaN, AlN and silicon.

Suitably, the semiconductor junction comprises a highly doped, p-type 3C—SiC nanofilm forming a heterojunction with a low-doped, p-type Si substrate. However, other crystalline forms of SiC can be used.

Suitably, the pair of electrodes are metal electrodes, such as aluminium electrodes, although other materials for the electrodes that can form an Ohmic contact with the upper layer can be used.

Suitably, the at least one parameter is one or more of the following: force; pressure; temperature.

In some embodiments, a force applied to the semiconductor material is detected based on a change in a resistance R of the semiconductor material due to the piezoresistive effect.

Suitably, the force is in the form of a mechanical stress or strain applied to the semiconductor junction which changes the carrier mobility and electrical resistivity in the semiconductor material. In some embodiments, the force is tensile strain or compressive strain.

In some embodiments, the sensing platform is in the form of a pressure sensor having a diaphragm structure, wherein the semiconductor material comprises a recessed or thinned region to which force is applied and in which stress or strain is concentrated.

Suitably, an external potential difference is applied between the pair of electrodes to create a tuning current I to modulate the piezoresistive effect in the semiconductor junction.

Preferably, detection of the force or pressure applied to the semiconductor material is based on a fractional change in the resistance, ΔR/R₀, where ΔR is the resistance change of the semiconductor material due to the piezoresistive effect, R₀ is the initial resistance of the semiconductor material between the pair of electrodes and R₀=V₀/I, where V₀ is the voltage between the pair of electrodes and I is the tuning current.

In some embodiments, the sensing platform is in the form of a temperature sensor.

Suitably, a tuning current I is applied between the pair of electrodes to create an external potential difference to modulate the thermoresistive effect in the semiconductor junction and thus the temperature coefficient of resistance (TCR) and sensitivity of the temperature sensor.

Suitably, detection of the temperature applied to the semiconductor material is based on a fractional change in the resistance, ΔR/R₀, where ΔR is the resistance change of the semiconductor material due to the thermoresistive effect, R₀ is the initial resistance of the semiconductor material between the pair of electrodes and R₀=V₀/I, where V₀ is the voltage between the pair of electrodes and I is the tuning current.

Suitably, the tuning current I is optimised to minimise R₀ and therefore maximise the sensitivity of the sensor. Preferably, the magnitude of the tuning current is controlled to be as close as possible to the magnitude of the photocurrent (the short-circuit current due to the photovoltaic effect) whilst maintaining stability.

According to another aspect, but not necessarily the broadest aspect, the present invention resides in a method of creating a sensing platform in a semiconductor junction comprising:

coupling a pair of electrodes to a surface of an upper layer of the semiconductor junction in a spaced apart relationship; and

illuminating a part of the surface of the semiconductor junction comprising at least part of one of the electrodes to create a lateral potential gradient between the pair of electrodes through the photovoltaic effect in the semiconductor;

wherein detecting at least one parameter by the sensing platform is based on measuring a change in electrical resistance of the semiconductor material due to the piezoresistive effect and/or the thermoresistive effect.

Preferably, the method comprises applying an external potential difference between the pair of electrodes to create a tuning current to modulate the piezoresistive effect in the semiconductor junction.

Suitably, the sensing platform is in the form of a temperature sensor and the method comprises applying a tuning current I between the pair of electrodes to create an external potential difference to modulate the thermoresistive effect in the semiconductor junction and thus the temperature coefficient of resistance (TCR) and sensitivity of the temperature sensor.

Suitably, the method comprises optimising the tuning current I to minimise R₀ and therefore maximise the sensitivity of the sensor. Preferably, the method comprises controlling the magnitude of the tuning current to be as close as possible to the magnitude of the photocurrent (the short-circuit current due to the photovoltaic effect) whilst maintaining stability.

Suitably, the method comprises applying a mechanical stress or strain to the semiconductor junction to change the carrier mobility and electrical resistivity in the semiconductor material.

Suitably, the method comprises applying thermal energy to the semiconductor junction to generate charge carriers and change the carrier mobility and electrical resistivity in the semiconductor material.

Further forms and/or features of the present invention will become apparent from the following detailed description.

### BRIEF DESCRIPTION OF THE DRAWINGS

In order that the invention may be readily understood and put into practical effect, reference will now be made to preferred embodiments of the present invention with reference to the accompanying drawings, wherein like reference numbers refer to identical elements. The drawings are provided by way of example only, wherein:

FIG. 1 shows a sectional representation of a sensing platform comprising a semiconductor junction according to an embodiment of the present invention;

FIG. 2 is a perspective view of a sensing platform including a tuning current according to an embodiment of the present invention;

FIG. 3 is a graph comparing fractional changes of resistance ΔR/R₀ between dark and light conditions under 451 ppm tensile strain;

FIG. 4 is a graph comparing fractional changes of resistance ΔR/R₀ between dark and light conditions under 451 ppm compressive strain;

FIG. 5 is a graph comparing fractional changes of resistance ΔR/R₀ between dark and light conditions under different tensile strains;

FIG. 6 is a graph comparing fractional changes of resistance AΔ/R₀ between dark and light conditions under different compressive strains;

FIG. 7 is a graph showing linear increases of ΔR/R₀ with increasing tensile strains under light conditions (main graph) and dark conditions (inset graph);

FIG. 8 is a graph showing linear increases of ΔR/R₀ with increasing compressive strains under light conditions (main graph) and dark conditions (inset graph);

FIG. 9A is a graph showing the change of the gauge factor (GF) with the tuning current I increasing from 15 μA to 45 μA;

FIGS. 9B, 9C and 9D are enlarged graphs of FIG. 9A showing the GF value versus the tuning current I in three distinguished current ranges;

FIG. 10 is a graph showing the variation of the generated lateral photovoltage under light intensities of 19,000 lux as the illumination is turned on and off;

FIG. 11 is a graph showing the variation of the generated photocurrent under light intensities of 19,000 lux as the illumination is turned on and off;

FIG. 12 is a graph showing the variation of the generated lateral photovoltage under light intensities of 19,000 lux as the position of the light source is moved from a left electrode to a right electrode of the sensing platform;

FIG. 13A shows photon excitation of electron-hole pairs in a 3C—SiC/Si sensing platform under light illumination;

FIG. 13B shows schematic band diagrams of the heterojunction of the sensing platform shown in FIG. 13A at electrode L without illumination;

FIG. 13C shows schematic band diagrams of the heterojunction of the sensing platform shown in FIG. 13A at electrode R with illumination;

FIG. 14A shows a 3C—SiC/Si sensing platform according to an embodiment of the present invention and energy-momentum (E-k) diagrams for the sensing platform at electrodes L, R, under inhomogeneous illumination of the electrodes L, R;

FIG. 14B shows the 3C—SiC/Si sensing platform of FIG. 14A and energy-momentum (E-k) diagrams for the sensing platform at electrodes L, R, under inhomogeneous illumination of the electrodes L, R and an applied tuning current;

FIG. 14C shows the 3C—SiC/Si sensing platform of FIG. 14A and energy-momentum (E-k) diagrams for the sensing platform at electrodes L, R, under inhomogeneous illumination of the electrodes L, R and an applied tuning current and applied strain;

FIG. 15 is a cross-sectional TEM image of an as-fabricated SiC nanofilm constructed on Si as used in embodiments of the sensing platform of the present invention;

FIG. 16 is a selected area electron diffraction (SAED) image of the 3C—SiC nanofilm shown in the image in FIG. 15;

FIG. 17 is an X-ray diffraction (XRD) graph of the 3C—SiC film grown on Si shown in the image in FIG. 15;

FIG. 18 is a perspective view of a sensing platform according to an embodiment of the present invention in the form of a strain sensor;

FIG. 19 is a side view of a SiC-Si heterojunction fabricated as a cantilever comprising a piezoresistors for the strain sensor shown in FIG. 18;

FIG. 20 is a plan view of the cantilever shown in FIG. 19;

FIGS. 21A to 21F illustrate a fabrication process of a 3CSiC/Si cantilever as used in the strain sensor shown in FIGS. 18 to 20;

FIG. 22 is a graph showing linear I-V characteristics for the SiC nanofilms and SiC/Si heterostructures carried out in darkness, at room temperature, under both dark and light conditions and in strain-free conditions;

FIG. 23 is a diagram showing an experiment to demonstrate the optoelectronic coupling effect of sensing platforms according to embodiments of the present invention;

FIG. 24 is a photograph of the experimental set up illustrated in FIG. 23;

FIG. 25 shows a side view and cross-sectional view of the 3CSiC/Si cantilever as used in the strain sensor shown in FIGS. 18 to 20 to illustrate the calculation of strain;

FIG. 26 shows perspective and cross-sectional views of a sensing platform in the form of a pressure sensor in accordance with another embodiment of the present invention;

FIG. 27 is a graph comparing fractional changes of voltage ΔV/V₀ between dark and light conditions under different pressures detected by the pressure sensor shown in FIG. 26;

FIG. 28 is a graph showing linear increases of V/V₀ with increasing pressures under light conditions detected by the pressure sensor shown in FIG. 26;

FIG. 28A illustrates a circuit model equivalent to the 3CSiC/Si heterojunction that forms the basis of sensing elements according to some embodiments of the present invention;

FIG. 29 is schematic diagram illustrating the coupling of photonic excitation and thermal excitation of charge carriers in a semiconductor junction in the form of an optothermotronic sensing platform according to other embodiments of the present invention;

FIG. 30 shows an experimental setup for the characterisation of the thermoresistive effect in SiC nanofilms and the optothermotronic effect in a sensing platform according to some embodiments of the present invention;

FIG. 31 is a graph showing current-voltage characteristics of SiC nanofilms of the sensing platform shown in FIG. 30 in dark conditions with varying temperature illustrating the thermoresistive effect;

FIG. 32 is a graph showing electrical resistance characteristics of SiC nanofilms of the sensing platform shown in FIG. 30 in dark conditions with varying temperature illustrating the thermoresistive effect;

FIG. 33 is a perspective representation of a sensing platform based on the coupling of photonic excitation and thermal excitation of charge carriers in a semiconductor junction according to some embodiments of the present invention;

FIG. 34 is a graph showing I-V measurements of the semiconductor junction of the sensing platform represented in FIG. 33 under fixed light illumination and constant room temperature, indicating linear I-V characteristics;

FIG. 35 is a graph showing I-V measurements of the semiconductor junction of the sensing platform represented in FIG. 33 under fixed light illumination and varying temperatures;

FIG. 36 is a graph showing relative voltage change with temperature variation of the semiconductor junction of the sensing platform represented in FIG. 33;

FIG. 37 is a graph showing the variation of TCR of the semiconductor junction of the sensing platform represented in FIG. 33 under light illumination and under darkness;

FIG. 38 is a graph showing the dependence of TCR of the semiconductor junction of the sensing platform represented in FIG. 33 on applied currents under light illumination with varying temperatures;

FIG. 39 is a graph showing an enlarged region of the graph shown in FIG. 38 around an applied current of approximately 7.6 μA;

FIG. 40A shows charge distribution at the p+-SiC/p-Si interface and a respective band energy diagram under dark conditions;

FIG. 40B shows the p+-SiC/p-Si interface shown in FIG. 40A and a respective band energy diagram under light illumination illustrating electron-hole pair (EHP) generation and transport in the SiC/Si heterojunction;

FIG. 40C shows the p+-SiC/p-Si interface shown in FIG. 40A and a respective band energy diagram under light illumination and heat illustrating thermally excited carriers and transport by thermal energy;

FIG. 41A is a representation of a p+-SiC nanofilm under illumination showing the photovoltage between two electrodes and a corresponding energy band diagram;

FIG. 41B shows the p+-SiC nanofilm of FIG. 41A under illumination and a corresponding energy band diagram with an offset voltage V₀ of approximately 10 μV under a bias current of 7.6 μA;

FIG. 41C shows the p+-SiC nanofilm of FIG. 41A under illumination with thermal excitation and a corresponding energy band diagram;

FIG. 42 is a graph illustrating the photogenerated voltage measured on a SiC nanofilm under four cycles of ON and OFF light illumination showing the repeatability of the photovoltage;

FIG. 43 is a graph illustrating the dependence of the photovoltage on temperature variation;

FIG. 44 is a graph illustrating the dependence of measured electric potential on temperature variation; and

FIG. 45 is a general flow diagram illustrating a method of creating a sensing platform in a semiconductor junction according to embodiments of the present invention.

Skilled addressees will appreciate that the drawings may be schematic and that elements in the drawings are illustrated for simplicity and clarity and have not necessarily been drawn to scale. For example, the relative dimensions of some of the elements in the drawings may be distorted to help improve understanding of the embodiments of the present invention.

### DETAILED DESCRIPTION OF THE INVENTION

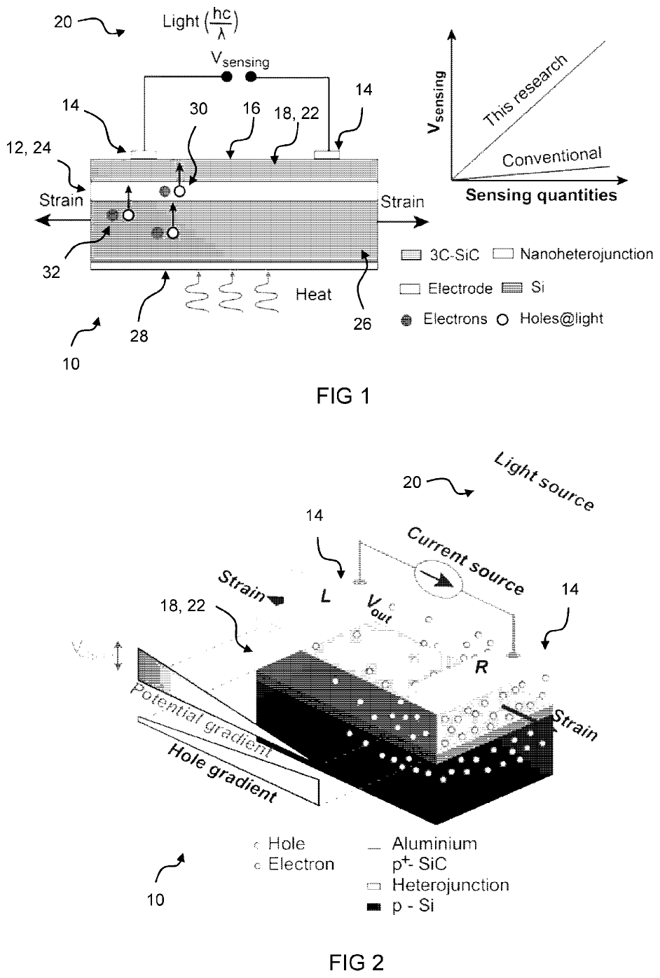

The present invention relates to sensing platforms comprising semiconductor junctions and methods of forming such sensing platforms. With reference to FIG. 1, an embodiment of the sensing platform 10 comprises a semiconductor junction 12 comprising a pair of electrodes 14 located on, or coupled to a surface 16 of an upper layer 18 of the semiconductor junction in a spaced apart relationship. The sensing platform 10 comprises a light source 20 to illuminate a part of the surface 16 of the upper layer 18 of the semiconductor junction 12 comprising at least part of one of the electrodes 14. Such asymmetric or uneven illumination of the electrodes 14 creates a lateral potential gradient between the pair of electrodes 14 through the photovoltaic effect in the semiconductor material. At least one parameter, such as force, pressure and/or temperature is detected by the sensing platform based on measuring a change in electrical resistance of the semiconductor material due to the piezoresistive effect and/or the thermoresistive effect.

In preferred embodiments, the semiconductor junction is in the form of a heterojunction comprising the upper layer 18 on a substrate 26. In preferred embodiments, the upper layer is in the form of a nanofilm that allows the light from the light source 20 to pass through and the substrate 26 absorbs the light and generates electron-hole pairs. Examples of materials for the substrate 26 include, but are not limited to small bandgap materials, such as silicon and germanium.

In some preferred embodiments, the semiconductor junction 12 comprises a silicon carbide/silicon (SiC/Si) heterojunction. In particular, in such preferred embodiments, the semiconductor junction 12 comprises a highly doped, p-type 3C—SiC nanofilm 22 forming a heterojunction 24 with a low-doped, p-type Si substrate 26. The sensing platform 10 also comprises a base electrode 28 adjacent the Si substrate 26 and on the opposite side of the semiconductor junction to the pair of electrodes 14 on the surface of the upper layer 18 of the semiconductor junction 12.

3C—SiC is used for the nanofilm 22 because of its relative ease of formation on the Si substrate 26, as will be described herein. However, it is envisaged that other crystalline forms of SiC can be used. Indeed, it is envisaged that in other embodiments of the sensing platform 10, other semiconductor materials and material combinations which possess a photovoltaic effect and a piezoresistive effect and/or thermoresistive effect can be used. Examples of such materials include, but are not limited to semiconductor materials, such as, but not limited to GaAs, GaN, AlN and silicon.

Generally, as will be described herein, the uneven or asymmetric illumination of the two spaced apart surface electrodes 14 creates a lateral potential gradient between the pair of electrodes 14 through the photovoltaic effect in the semiconductor material. Such semiconductor junction 12 provides a platform for a range of sensors with significantly enhanced sensitivity based on a large change in the lateral potential gradient resulting from the generation and repopulation of charge carriers, i.e. holes 30 or electrons 32, under light illumination and the electric field modulation of carrier energy. The semiconductor junction 12 forms a diode to allow the charge carriers to travel in only one direction from the substrate 26 to an upper layer 18 of the semiconductor junction 12.

Some embodiments of the present invention include the detection of force, such as, but not limited to stress or strain 34 as will be described herein. Strain-induced energy band shifts of heavy holes and light holes in the semiconductor material result in a change in carrier mobility and electrical resistivity in the semiconductor material. Detection of the force or pressure applied to the semiconductor material is based on a fractional change in the resistance, ΔR/R₀, where ΔR is the resistance change of the semiconductor material due to the piezoresistive effect, R₀ is the initial resistance of the semiconductor material between the pair of electrodes 14 and R₀=V₀/I, where V₀ is the voltage between the pair of electrodes 14 and I is a tuning current.

In some embodiments, the sensing platform provides a temperature sensor with significantly enhanced sensitivity. Detection of the temperature applied to the semiconductor material is based on a fractional change in the resistance, ΔR/R₀, where ΔR is the resistance change of the semiconductor material due to the thermoresistive effect, R₀ is the initial resistance of the semiconductor material between the pair of electrodes 14 and R₀=V₀/I, where V₀ is the voltage between the pair of electrodes 14 and I is the tuning current.

According to some embodiments of the present invention, a giant piezoresistive effect is achieved in the semiconductor heterojunction 12 by coupling the photoexcitation of charge carriers, strain modification of carrier mobility and electric field modulation of carrier energy. The light source 20 is a visible light source which illuminates the top layer 18 of material of the heterojunction structure non-uniformly or asymmetrically such that the two surface electrodes 14 are not evenly illuminated. This generates a lateral photovoltage which is counteracted by a controlled external electric field to significantly modulate the magnitude of the piezoresistive effect. The 3C—SiC nanofilm 22 is grown on the Si substrate 26 to form the 3C—SiC/Si heterojunction. For some embodiments of the sensing platform, under visible light illumination, a stable gauge factor (GF) value of the SiC/Si heterojunction has been achieved as high as approximately 58,000, which is the highest value ever reported for semiconductor piezoresistive sensors.

In some embodiments of the sensing platform 10, the piezoresistive effect in the SiC nanofilm 22 is utilised to detect force, such as mechanical stress or strain. When a force is applied to the semiconductor material, the force can be detected and measured based on a change in a resistance R of the semiconductor material due to the piezoresistive effect. The force applied to the semiconductor material changes the carrier mobility and electrical resistivity in the semiconductor material.

In some embodiments, an external potential difference is applied between the pair of electrodes 14 to create a tuning current to modulate the piezoresistive and thermoresistive effects in the semiconductor junction 12. Thus, the sensitivity of the sensing platform 10 is boosted by optimally and simultaneously regulating both the lateral photovoltage and the tuning current. While heavily doped p-type 3C SiC p-type Si (p+-SiC/p-Si) is used in preferred embodiments of the sensing platform, it is envisaged that the sensitivity of other materials and smart structures that have simultaneous photovoltaic and piezoresistive properties can be enhanced.

In some embodiments, thermal energy is detected by the sensing platform and the temperature is measured based on a change in a photovoltage V of the semiconductor material due to the thermoresistive effect.

FIG. 2 is a perspective view of a sensing platform 10 according to an embodiment of the present invention which further illustrates the enhancement of the piezoresistive effect by optoelectronic coupling in a 3C—SiC/Si heterojunction. The piezoresistive effect in the 3C—SiC/Si heterojunction is modulated by visible light from the light source 20 which non-uniformly illuminates and penetrates the surface 16 of the upper layer 18 of the 3C—SiC nanofilm 22 creating a lateral potential gradient between the pair of spaced apart electrodes 14 (left (L) and right (R)) through the photovoltaic effect in the semiconductor material. In this embodiment, the photovoltaic effect is coupled with an optimally controlled tuning current.

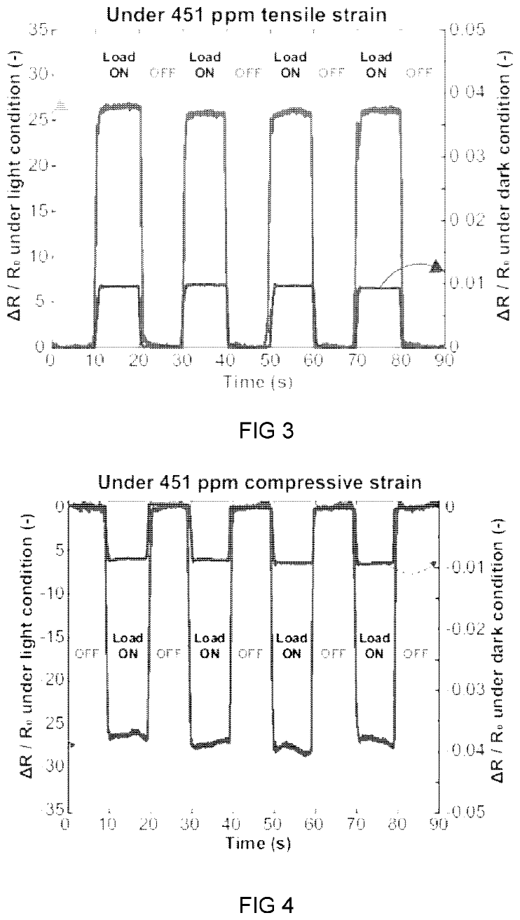

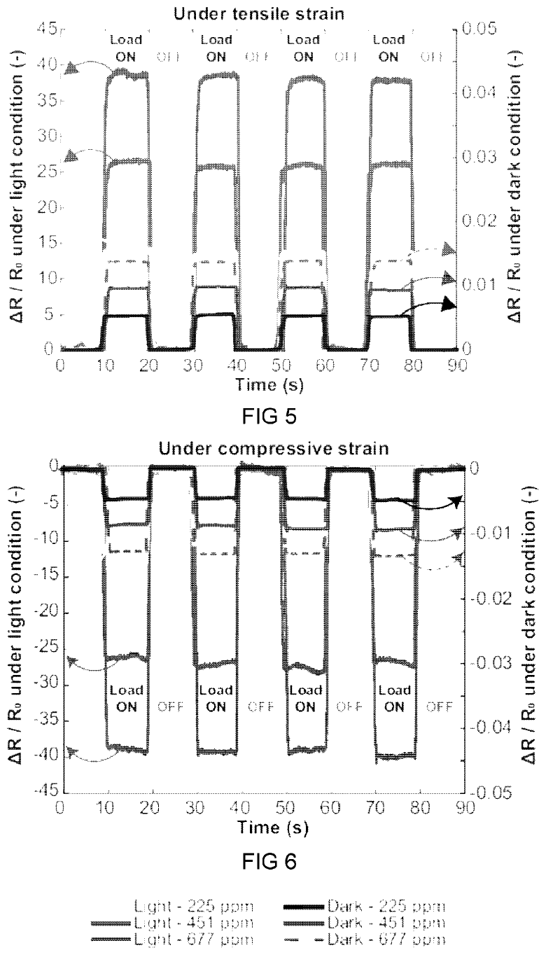

An unprecedentedly large piezoresistive effect was achieved in embodiments of the sensing platform of the present invention based on a heavily doped p-type 3C—SiC/p-type Si heterojunction using a bending method, as described in detail hereinafter. The carrier concentrations in the 3C—SiC nanofilm 22 and Si substrate 26 were 5×10¹⁸ cm⁻³ and 5×10¹⁴ cm⁻³, respectively. The light intensity was 19,000 lux, while three different strains of 225 ppm, 451 ppm, and 677 ppm were induced in the heterojunction. An optimally controlled tuning current was supplied and the output voltage was simultaneously measured. The tuning current was constant at 29.75 mA. The strains were periodically applied (i.e. Load ON) and released (i.e. Load OFF). FIG. 3 compares the fractional changes of resistance ΔR/R₀ between dark and light conditions under 451 ppm tensile strain while FIG. 4 shows ΔR/R₀ under 451 ppm compressive strain. The fractional change of resistance ΔR/R₀ is calculated as follows:

$$\frac{Δ R}{{R}_{0}} = \frac{R - {R}_{0}}{{R}_{0}} = \frac{\frac{V}{I} - \frac{{V}_{0}}{I}}{\frac{{V}_{0}}{T}} = \frac{V - {V}_{0}}{{V}_{0}} = \frac{Δ V}{{V}_{0}} \qquad ( 1 )$$

where the strain-free resistance R₀ is calculated by R₀=V₀/I. V₀ is the voltage measured between the two electrodes under strain-free conditions, and I is the supplied tuning current flowing between the two electrodes 14, which was kept constant throughout the measurement. When a strain/stress is applied, the resistance R will change due to the piezoresistive effect. The value of resistance is calculated by R=V/I, where V is the voltage measured between the two electrodes 14 under the application of stress/strain. Under a tensile strain of 451 ppm, ΔR/R₀ increased approximately 2,950 times from 0.009 in the dark condition to 26.6 under light illumination. This trend is similar under the compressive strain. ΔR/R₀ increased from −0.0087 to −27 corresponding to the 451 ppm compressive strain. These results indicate a giant enhancement of piezoresistive sensitivity under light conditions. This tremendous enhancement was confirmed with other applied strains as shown in FIGS. 5 and 6. FIG. 5 compares fractional changes of resistance ΔR/R₀ between dark and light conditions under tensile strains of 225 ppm, 451 ppm, and 677 ppm. FIG. 6 compares fractional changes of resistance ΔR/R₀ between dark and light conditions under compressive strains of 225 ppm, 451 ppm, and 677 ppm.

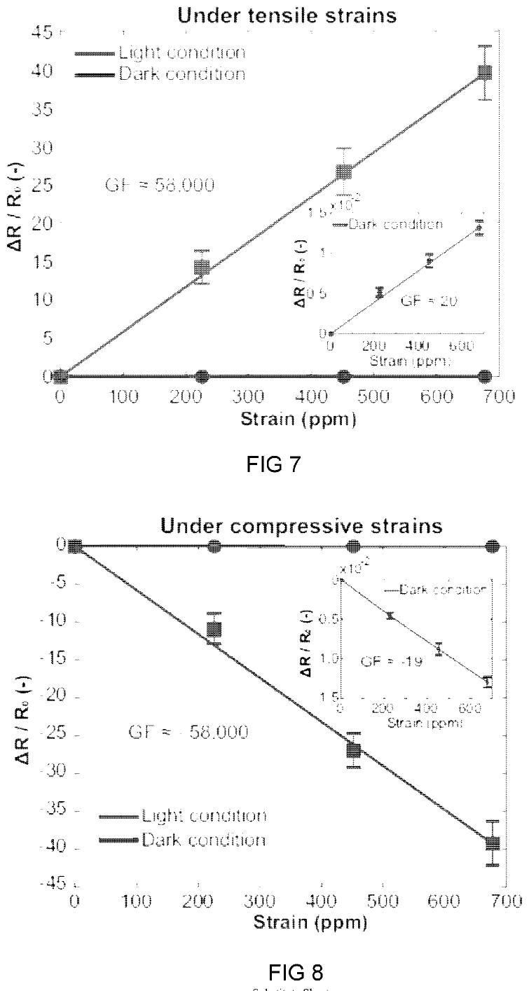

FIG. 7 shows the linear increases of ΔR/R₀ with the increasing tensile strains under light conditions (main graph) and under dark conditions (inset graph). FIG. 8 shows the linear increases of ΔR/R₀ with the increasing compressive strains under light conditions (main graph) and under dark conditions (inset graph). The linearity of the device is excellent which is desirable for high-performance strain sensing applications. The unprecedented high gauge factor (GF) was achieved by simultaneously utilizing the lateral photovoltage and tuning electric current to modulate the performance of the piezoresistive effect under the tensile strains as shown in FIG. 7 and under the compressive strains shown in FIG. 8.

The piezoresistive sensitivity is characterised by GF defined as fractional resistance change to the applied strain as follows:

$$GF = \frac{Δ R}{{R}_{0}} \times \frac{1}{ε} = \frac{Δ V}{{V}_{0}} \times \frac{1}{ε} \qquad ( 2 )$$

where ε is the applied strain as detailed herein with reference to FIG. 25 and Equations (4) and (5). With reference to FIG. 7, under tensile strain, the GF was found to be 20 in the absence of light (inset graph) and the GF increased to around 58,000 under light illumination (main graph) which is the highest strain sensitivity ever reported. Meanwhile, under compressive strain, the change of resistance or GF was similar, but opposite in sign with that under the tensile strain.

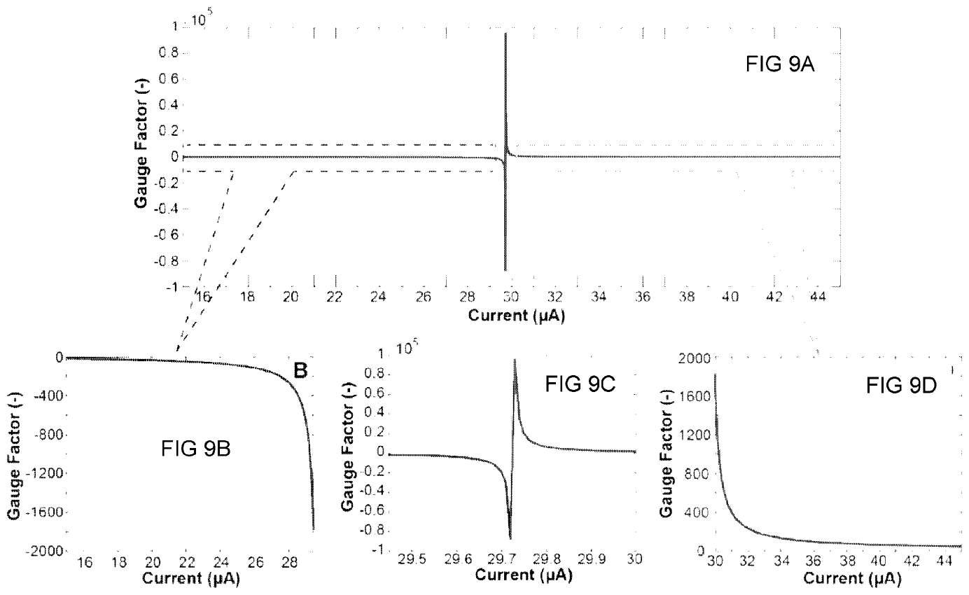

The dependence of the piezoresistive effect on the supplied tuning current I under the tensile strain of 451 ppm and under illumination of 19,000 lux intensity is depicted in FIGS. 9A-9D. FIG. 9A shows the change of the GF with the tuning current I increasing from 15 μA to 45 μA. FIGS. 9B, 9C and 9D illustrate enlarged graphs of the GF value versus the tuning current I in three distinguished current ranges. With reference to FIG. 9B, the GF increases from approximately −16 to −1,800 as the current I increases from 15 μA to 29.45 μA. With reference to FIG. 9D, the GF decreases from 1,800 to about 50 for a high current ranging from 30 μA to 45 μA. This is attributed to the dominance of the photo-modulated potential relative to the injected potential (i.e. the tuning current I). The compensation of these two potentials in the current range of 29.45 μA to 30 μA has led to a change of sign in the GF, as well as the ultra-high absolute GF values, as shown in FIG. 9C.

As the strain-free voltage V₀ is relatively small due to the potential compensation, the modulation of charge mobility under strain resulted in a significant change of the measured voltage, resulting in an ultra-high GF. It was observed that higher GF values can be achieved as the magnitude of the tuning current is brought closer to that of the photocurrent. For instance, under incident light intensity of 19,000 lux, the maximum GF observed was as high as 95,500. However, as the tuning current I approached closer to the photocurrent, the GF was more vulnerable to slight variations of the photocurrent. Therefore, in order to achieve higher stable sensitivity, the tuning current I should be controlled as close as possible to the magnitude of the photocurrent, but far enough away to maintain stability. Hence, the value of approximately 58,000 represents a stable GF achieved based on a constant tuning current of 29.75 μA under illumination conditions of 19,000 lux intensity from a stable visible light source.

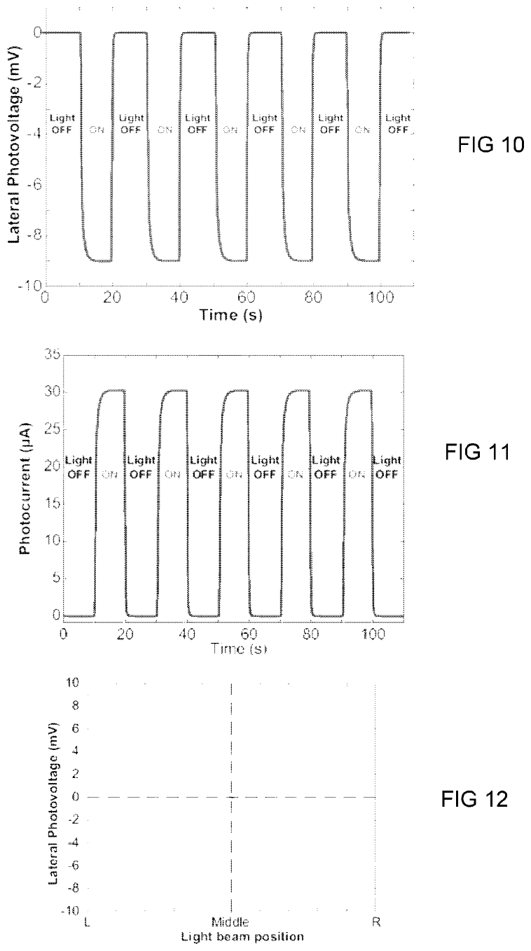

As such, in some embodiments of the sensing platform of the present invention, the significant enhancement of the piezoresistive effect by optoelectronic coupling in the 3C—SiC/Si heterojunction is a result of a combination of two key elements—light illumination and tuning current. This enhancement is firstly attributed to the photogenerated electrical potential in the 3C—SiC nanofilm 22 with non-uniform illumination of the spaced apart electrodes 14 by visible light which was indicated by the lateral photovoltage and/or the photocurrent between the two electrodes 14. The magnitudes of the photovoltage and the photocurrent can be manipulated by parameters such as light intensity, light position and/or light wavelengths. With reference to FIG. 10, the lateral photovoltage, for example, was measured to be approximately −9 mV under light intensities of 19,000 lux and 0 mV with the light turned off. With reference to FIG. 11, the value of the photocurrent was around 29.7 μA under light intensities of 19,000 lux and 0 μA with the light turned off.

The magnitudes of generated photovoltage and photocurrent can be changed by changing light position. For instance, with the same light intensity of 19,000 lux, the position of the light beam was gradually adjusted from the left (L) electrode 14 to the right (R) electrode 14. With reference to FIG. 12, the measured voltage decreased from a large positive value (e.g. 9 mV) at the electrode L to zero at the centre of the device, then increased to a large negative value at the electrode R (e.g. −9 mV).

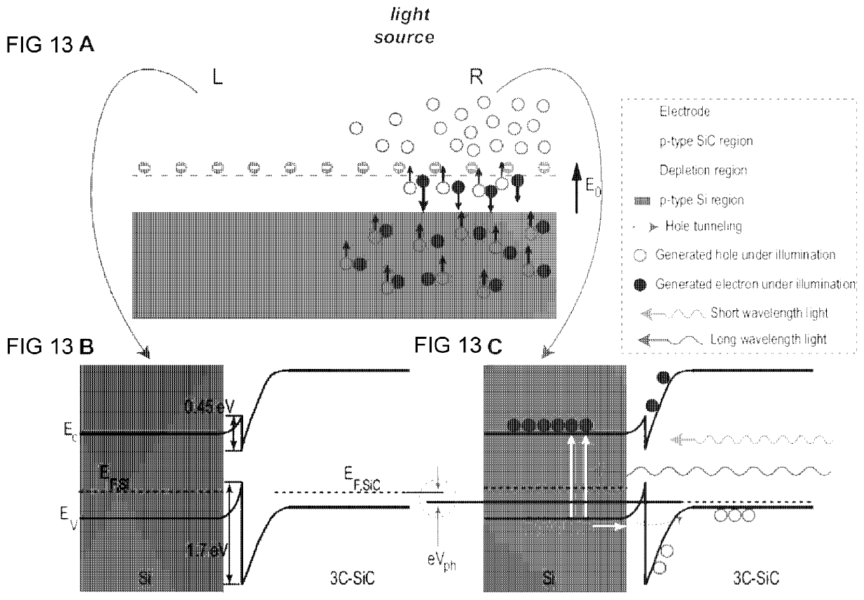

The underlying physics behind the generation of photocurrent and photovoltage on the 3C—SiC can be explained according to the lateral photoeffect. FIG. 13A shows the photon excitation of electron-hole pairs in the 3C—SiC/Si sensing platform according to some embodiments of the present invention under light illumination. As such, photo-generated charge carriers (holes and electrons) have a high concentration at the electrode R close to the light source 20. The formation of the gradient of charge carriers is discussed as follows.

When heavily doped p-type 3C—SiC and p-type Si are brought together, holes diffuse from the 3C—SiC film 22 into the Si substrate 26 due to the decrease of the hole gradient, leaving behind negative charges in the SiC layer near the interface of the heterojunction. In contrast, electrons in the Si, as minor carriers, migrate into the SiC film and create a positive charge layer in the Si side. The migration of electrons and holes forms a depletion region (space charge region) and a built-in electric field E₀ which bends the conduction band and valence band at the depletion region. It is worth noting that the depletion region extends primarily into the Si substrate, as shown in FIG. 13A, because the carrier concentration in the Si substrate 26 (5×10¹⁴ cm⁻³) is much lower than the carrier concentration in the SiC thin film 22 (5×10¹⁸ cm⁻³).

As shown in FIGS. 13B and 13C, there are energy offsets of 0.45 eV and 1.7 eV for the conduction band and valence band, respectively, between the 3C—SiC film 22 and the Si substrate 26. FIGS. 13B and 13C show the band energy diagrams of SiC/Si without light illumination at electrode L and under light illumination at electrode R, respectively. Owing to the visible-blind property of SiC, photons were only absorbed in the depletion region and the Si layer, where electron-hole-pairs (EHPs) were generated. The generated EHPs in the depletion region were separated by the internal electric field E₀. Consequently, photogenerated holes in the depletion region moved to the SiC film 22 and increased its electrical conductivity. It is hypothesized that the photogenerated holes in the Si substrate 26 also moved towards the SiC film 22 by the tunneling mechanism. Under the non-uniform illumination, the majority of photons migrated into the area of electrode R. Hence, more holes were injected into this area, while there were fewer holes being generated in the vicinity of electrode L. Consequently, there was a potential gradient of hole concentration from electrode R to electrode L, which resulted in a difference of electric potential described as eVₚₕ=E_{F, SiC@R}−E_{F, SiC@L}, where e is the elementary charge, E_{F, SiC} is the Fermi energy level, and Vₚₕ is the generated lateral photovoltage. When the external circuit is shorted, the only current in the circuit is the photocurrent (Iₚₕₒₜₒ).

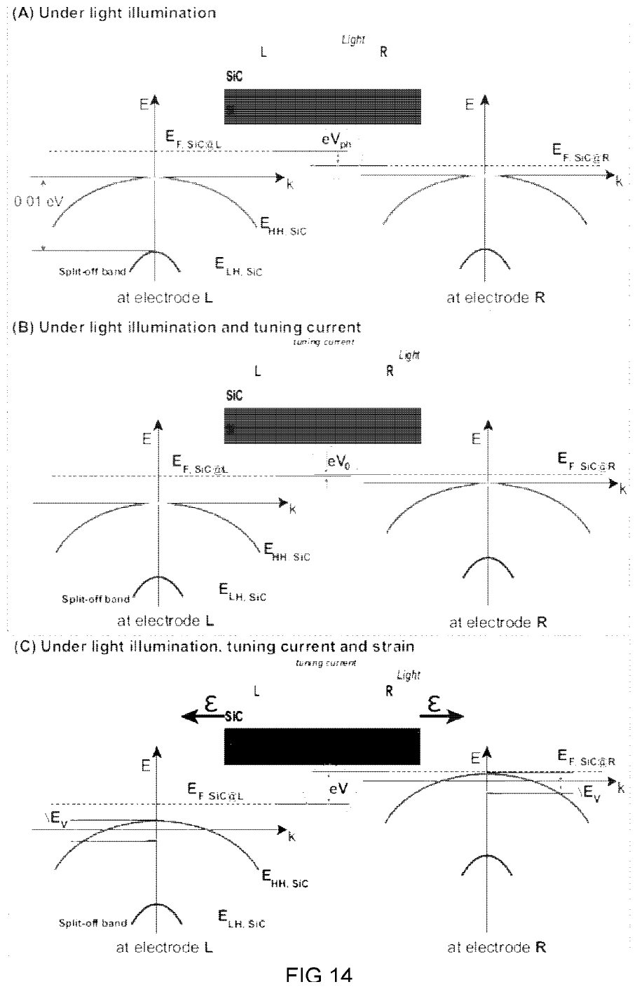

The potential gradient of hole concentration from electrodes R to L can also be represented in the energy-momentum (E-k) diagrams shown in FIGS. 14A-C. With reference to FIG. 14A, under the inhomogeneous, asymmetric or uneven illumination of the electrodes L, R by the light source 20, the difference in photogenerated hole concentration at R and L resulted in a difference of Fermi levels in the SiC thin film 22 at the two electrode regions. With reference to FIG. 14B, when a bias current j is applied with the positive terminal at electrode R and the negative terminal at electrode L, the 3C—SiC band energy is bent upwards from electrode L to electrode R. The bias current j creates an electric field E_{b}:

$${E}_{b} = {\int }_{L}^{R} j \cdot \frac{1}{σ} dx \qquad ( 3 )$$

where σ and x are the conductivity of the charge carrier and the distance from electrode L, respectively. The electric field E_{b} offsets the lateral photogenerated electric field Eₚₕ=eVₚₕ, resulting a relatively small voltage V₀ between the two electrodes. Particularly, under the light intensity of 19,000 lux, a bias current of 29.75 mA almost cancels out the lateral photovoltage, resulting in a nearly zero voltage (V₀≈0), as shown in FIG. 14B.

FIG. 14C shows the change in the band diagram at the electrodes L, R under a uniaxial tensile strain. The energy band of heavy holes (HH) is shifted up to a lower energy level while the energy band of light holes (LH) is moved down to a higher energy level. As a consequence, there is an increase of HH concentration and a decrease of LH concentration while the total concentration of holes was hypothesized to be unchanged due to the high doping concentration. It should be pointed out that, as HHs have a higher effective mass than LHs, the increase of HH concentration and the decrease of LH concentration caused an increase in the total effective mass. Consequently, the mobility of holes reduced which diminished the conductivity G or increased resistance. As a result, the bias current j generated a high electric field E and a high measured voltage V. The significant difference between the voltage V under light illumination coupled with applied strain, as shown in FIG. 14C, with respect to the nearly zero voltage V₀ under the strain-free state shown in FIG. 14B lead to the giant piezoresistive effect in the SiC nanofilm. Furthermore, in principle, it is possible to tune V₀ toward zero by regulating the illumination condition and tuning the current to achieve desirable giant sensitivity to strain.

The giant gauge factor (GF) of 58,000 achieved in some embodiments of the 3C—SiC/Si heterojunction sensing platform of the present invention under optoelectronic coupling is the highest GF reported to date and is about 30,000 times greater than the GF of commercial metal strain gauges, and more than 2,000 times higher than that of 3C—SiC in dark conditions. Three parameters contribute to this tunable giant piezoresistive effect. Firstly, the non-uniform illumination created the gradient of carrier concentration within the top layer of the 3C—SiC nanofilm 22, generating a lateral photovoltage in this layer. Secondly, the tuning current I reduces the difference of Fermi energy levels in the 3C—SiC at the two electrodes 14 (L and R). Depending on the value of the lateral photovoltage, the optimal tuning current can have different values. Thirdly, mechanical stress/strain caused shifts of the valance bands (light holes and heavy holes), leading to the redistribution of charge carriers among these bands, and therefore, changing the mobility and electrical conductivity of the material. The sensing platforms of the present invention employing such optoelectronic coupling in semi-conductor heterojunctions thus enables a range of ultra-sensitive sensors to be realised. For example, when a force is applied to the semiconductor material, the force can be detected and measured based on a change in a resistance R of the semiconductor material due to the piezoresistive effect.

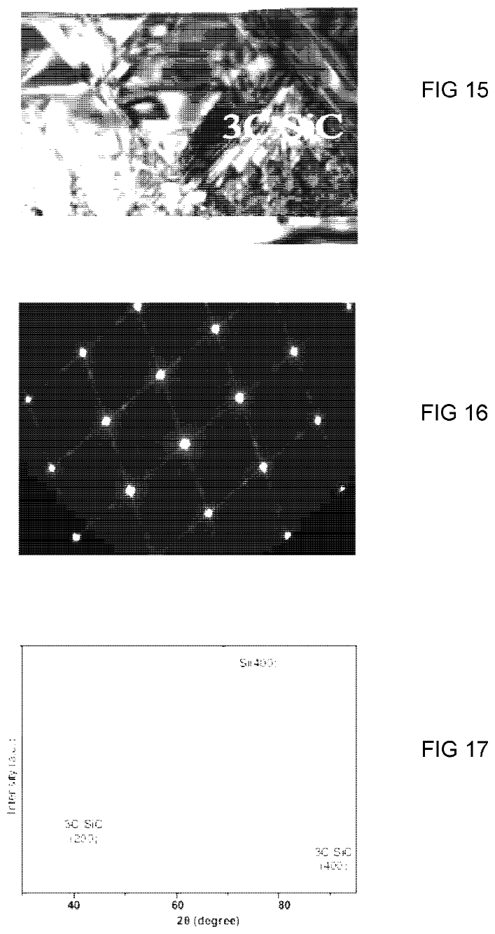

Growth 3C—SiC on Si substrate. According to one method of production of the sensing platform, single crystalline cubic silicon carbide (3C—SiC) was grown on a single crystalline Si substrate by Low Pressure Chemical Vapour Deposition (LPCVD) in a 1,000° C. reactor. Ultra-pure silane and acetylene were used as precursor materials for providing Si and C elements in the 3C—SiC growth process. Heavily doped 3C—SiC was formed by doping aluminium atoms from (CH₃)₃Al (trimethylaluminium) precursor compound in the in situ growth process. Characteristics of single crystalline 3C—SiC on single crystalline Si substrate are shown in FIGS. 15 to 17. FIG. 15 shows the Transmission Electron Microscope (TEM) image of the cross-sectional area between the SiC and Si showing the crystallinity of SiC nanofilms that was confirmed by the selected area electron diffraction (SAED) measurements shown in FIG. 16. FIG. 17 is an X-ray diffraction (XRD) graph indicating the formation of the 3C—SiC film epitaxially grown on the Si substrate.

The TEM image in FIG. 15 confirms the crystalline properties of the SiC film. The thickness of 3C—SiC layer measured by NANOMETRICS Nano-spec-based measurements was 300 nm with the tolerance across the wafer within ±2 nm. The carrier concentrations in 3C—SiC layer and single crystalline Si substrate were 5×10¹⁸ cm⁻³ and 5×10¹⁴ cm⁻³, respectively, determined by the hot probe and Hall effect techniques.

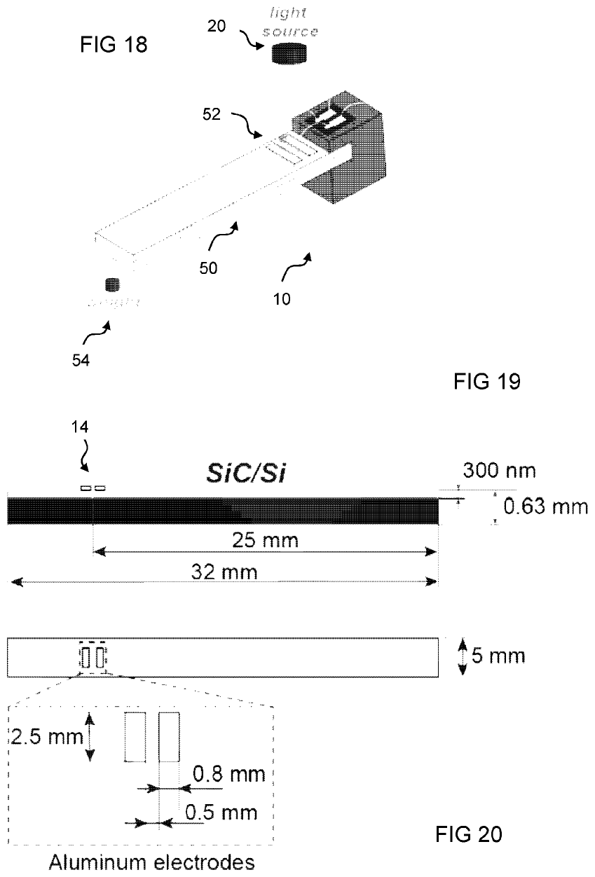

Sample fabrication. To demonstrate the piezoresistive effect by optoelectronic coupling in a heterojunction, sensing platforms in the form of strain sensors comprising a cantilever were fabricated as shown in FIGS. 18 to 20. The sensing platform 10 comprises a cantilever 50 formed from a SiC—Si semiconductor heterojunction. The cantilever 50 comprises a piezoresistor 52 towards one end of the cantilever comprising a pair of spaced apart aluminium electrodes 14. The cantilever 50 is clamped, or otherwise secured at one end near the piezoresistor 52. A tuning current I is applied from a current source across the electrodes 14. A light source 20 unevenly illuminates the electrodes 14. A weight 54 is applied at the opposite end of the cantilever 50. In the examples, shown, the length, width, and thickness of the cantilever 50 are respectively 32 mm, 5 mm, and 0.63 mm. The thickness of the SiC film is 300 nm. The distance from the free end of the cantilever 50 to the center of piezoresistor 52 is 25 mm. The dimension of the piezoresistor is 0.5 mm×2.5 mm, while that of the electrodes is 0.8 mm×2.5 mm. It will be appreciated that the present invention is not limited to these particular dimensions.

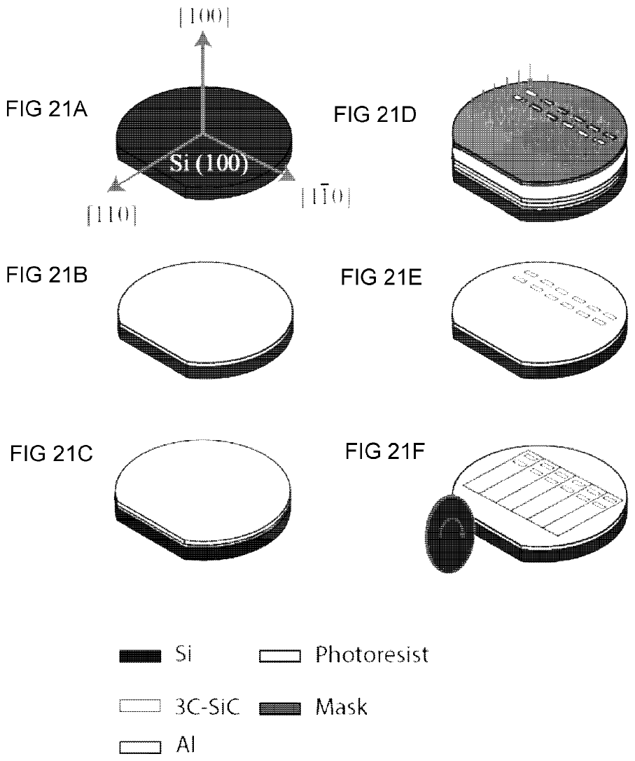

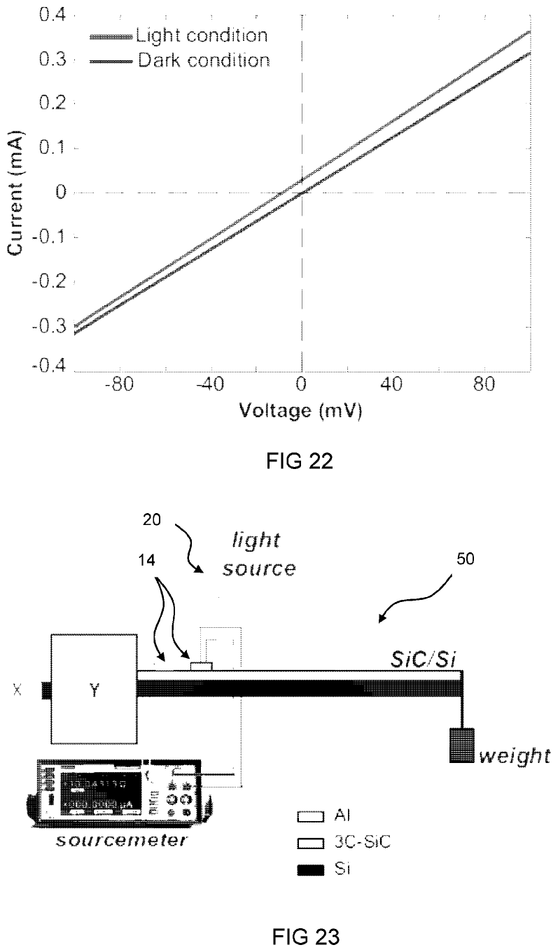

Five cantilevers were fabricated following a process illustrated in FIGS. 21A to 21F. With reference to FIG. 21A, the fabrication process of the 3C—SiC/Si cantilever starts from a p-type Si wafer (100) having a doping concentration of 5×10¹⁴ cm⁻³. With reference to FIG. 21B, the 3C—SiC nanofilm with a thickness of 300 nm is epitaxially grown on the (100) Si substrate by LPCVD. With reference to FIG. 21C, an aluminium layer was deposited on top of the 3C—SiC layer by a sputtering process. With reference to FIG. 21D, a photoresist layer was coated on the surface of aluminium by a spin-coat technique at a spinning speed of 3,500 rpm and the photoresist layer was baked under 110° C. for 100 seconds. Next, the wafer was exposed to ultraviolet light to pattern shape of the electrodes. With reference to FIG. 21E, the aluminium electrodes were formed through an aluminium wet etching process. With reference to FIG. 21F, the 3C—SiC/Si wafer was diced to form the cantilevers. A root mean square roughness of the top surface of the cantilever estimated by Atomic Force Microscopy measurements was smaller than 15 nm. Current-voltage measurements for the SiC nanofilms and SiC/Si heterostructures were carried out in darkness and at room temperature. As shown in FIG. 22, the I-V characteristics were linear under both dark and light condition which confirmed that an Ohmic contact was formed between the aluminium electrodes 14 and the 3C—SiC layer 22.

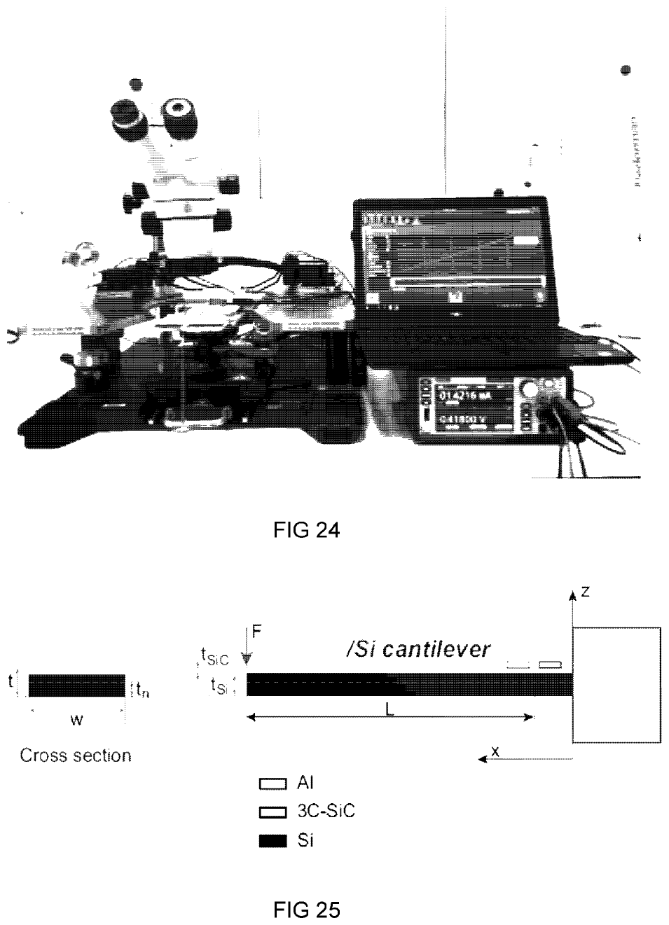

Optoelectronic coupling characterisation. To characterize the optoelectronic coupling effect of the sensing platforms of the present invention, five cantilevers 50 were tested in the same conditions and with the same procedure. As shown in the diagram in FIG. 23 and the photograph of the experimental set-up in FIG. 24, the cantilevers 50 were mounted on a chuck of an EP 6 CascadeMicrotech probe system. The position of the cantilever 50 can be accurately adjusted. The cantilevers 50 were illuminated from above by vertical visible light from a light source 20 in the form of a Fiber Optic Illuminator used in the EP 6 CascadeMicrotech probe system. The light beam position can be precisely controlled by using a precision XYZ stage. Light intensity was measured by using a digital lux meter and was 19,000 lux. The tensile and compressive strains on the SiC/Si sensing platforms were induced by using a cantilever bending experiment. Three different weights of 50 g, 100 g, and 150 g were hung on the free end of the cantilevers 50 to induce strains in the sensing element. The tuning electric current I was controlled and the voltage was simultaneously measured between the two electrodes 14 by using a KEITHLEY 2450 Source Meter.

The calculation of strain as measured by the strain sensor shown in FIGS. 18 to 20 is now described with further reference to FIG. 25, which depicts a cantilever 50 with one end clamped and one end free. The width and thickness of the cantilever are w and t, respectively. The distance from the free end (load point) to the centre of the piezoresistor is L. t_{Si} and t_{SiC} are the thickness of the Si substrate and the SiC thin film, respectively. E_{Si} and E_{SiC} are Young's moduli of Si and SiC, respectively in the [100] orientation. A force F is applied to the free end of the cantilever. The strain ε in the centre of the piezoresistor is calculated by using a bending model of a bi-layer beam as SiC was epitaxially grown on a Si substrate with the assumption that the bonding between the Si substrate and SiC layer is perfect. As the lengths of the Si substrate and SiC layer are equal, the lateral strain of the piezoresistor is:

$$ε = \frac{F}{wD} {Lt}_{n} = \frac{F}{wD} L \frac{t}{2} \qquad ( 4 )$$

where tₙ is the distance from the neutral axis to the piezoresistor. The bending modulus per unit is estimated as:

$$D = \frac{{E}_{Si}^{2} {t}_{Si}^{4} + {E}_{SiC}^{2} {t}_{SiC}^{4} + 2 {E}_{Si} {E}_{SiC} {t}_{Si} {t}_{SiC} ( 2 {t}_{Si}^{2} + 3 {t}_{Si} {t}_{SiC} + 2 {t}_{SiC}^{2} )}{12 ( {E}_{Si} {t}_{Si} + {E}_{SiC} {t}_{SiC} )} \qquad ( 5 )$$

Substitute the given parameters into equations (4) and (5) provides the strain at the cantilever forming the sensing element corresponding with three applied loads of 50 g, 100 g, and 150 g as shown in Table 1 below. The results have also been confirmed using a finite element analysis (FEA) method.

TABLE 1

| Load | F | w | t | L | E_{Si} | E_{SiC} | ε |
|---|---|---|---|---|---|---|---|
| (g) | (mN) | (mm) | (mm) | (mm) | (GPa) | (GPa) | (ppm) |
| 50 | 491 | 5 | 0.63 | 25 | 170 | 330 | 225 |
| 100 | 982 | 5 | 0.63 | 25 | 170 | 330 | 451 |
| 150 | 1473 | 5 | 0.63 | 25 | 170 | 330 | 677 |

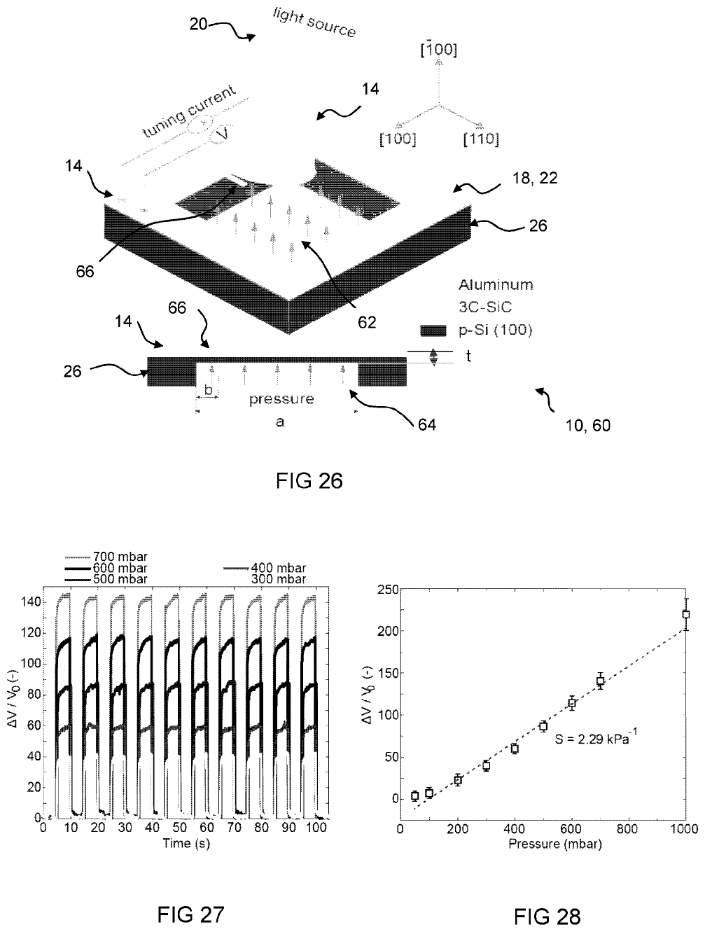

FIG. 26 illustrates another embodiment of the sensing platform 10 in the form of a pressure sensor 60. The pressure sensor 60 is formed from a 3C—SiC/Si semiconductor heterostructure comprising a SiC upper layer 18 in the form of a SiC nanofilm 22 formed on a Si substrate 26 as described herein. The pressure sensor 60 comprises spaced apart aluminium electrodes 14 formed on the upper layer 18 as described herein. The pressure sensor 60 has a square configuration having a diaphragm structure 62. The diaphragm structure 62 is formed in the Si substrate 26 of the semiconductor material wherein the Si substrate 26 comprises a recessed or thinned region 64 to which force is applied and thus pressure is detected by the pressure sensor 60 as described herein. The recessed or thinned region 64 of the semiconductor material in this embodiment is substantially square or rectangular in shape and has side length a and thickness t. A portion of the aluminium 14 overlaps the recessed or thinned region 64 by a distance b, which forms the resistor 66 (sensing element) at the edge of the diaphragm 64 between the two electrodes 14. Dimensions a and t affect the deformation of the diaphragm 64 under pressure and therefore affect the sensitivity. A larger area diaphragm (greater a) and/or a thinner diaphragm (smaller t) offers higher sensitivity. A portion of the SiC upper layer 18 comprising at least part of one of the electrodes 14 and the recessed or thinned region 64 is illuminated by a visible light source 20 positioned above the upper layer 18. A tuning current I is applied between the electrodes 14 and the photovoltage V across the electrodes 14 is measured as described herein. The position of the light source 20 is arranged close to one electrode 14 to generate the light gradient and therefore a lateral photovoltage between the two electrodes 14. It will be appreciated that the pressure sensor according to embodiments of the present invention are not limited to the particular configuration shown in FIG. 26 and described above. Pressure sensors according to embodiments of the present invention can have other shapes and configurations according to the particular application.

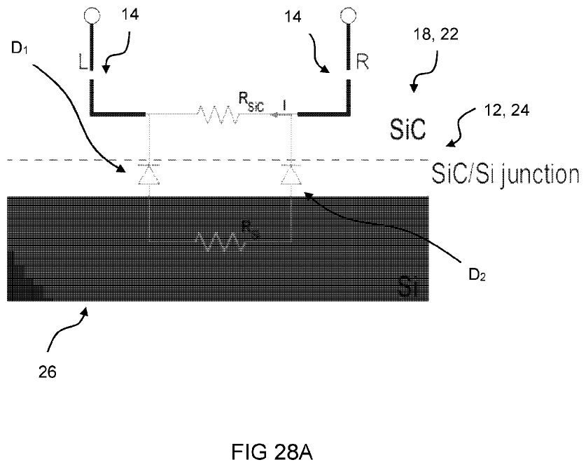

FIG. 27 is a graph comparing fractional changes of voltage ΔV/V₀ over time between alternating dark and light conditions under different pressures detected by the pressure sensor 60 shown in FIG. 26. FIG. 27 shows peaks in the fractional changes of voltage ΔV/V₀ under light conditions detecting applied pressures of 300 mbar, 400 mbar, 500 mbar, 600 mbar and 700 mbar. Under dark conditions in between the light conditions the fractional changes of voltage ΔV/V₀ drop to substantially zero. FIG. 28 is a graph showing linear increases of ΔV/V₀ with increasing pressures under light conditions detected by the pressure sensor shown in FIG. 26.

FIG. 28A illustrates a circuit model equivalent to the 3CSiC/Si heterojunction that forms the basis of sensing platforms and sensing elements according to some embodiments of the present invention. The p-Si substrate 26 and heterojunction 24 play critical roles in the generation and redistribution of charge carriers (electron/hole pairs) into the 3C—SiC thin film 22. The sensing element is in the form of a SiC thin film resistor R_{SiC} defined by two electrodes 14 (L, R). A diode configuration comprising diodes D₁, D₂ and resistor R_{Si} represents the heavily doped p-type 3C—SiC/p-type Si heterojunction 24, which only allows the charge carriers to move from the Si side to SiC whenever there are excessive charge carriers in the Si, e.g., due to photon excitation. Therefore, this heterojunction configuration works well either when the Si substrate is floated or kept at a potential lower than the potential on the SiC side to maintain the reverse-biased condition. This was demonstrated by experiments in both cases, i.e. when the Si substrate 26 was grounded and when the Si substrate 26 was floated, and the results were similar.

Coupling of Photonic Excitation and Thermal Excitation of Charge Carriers in a Semiconductor Junction.

According to other embodiments, the present invention is directed to sensing platforms based on the coupling of photonic excitation and thermal excitation of charge carriers in a semiconductor junction.

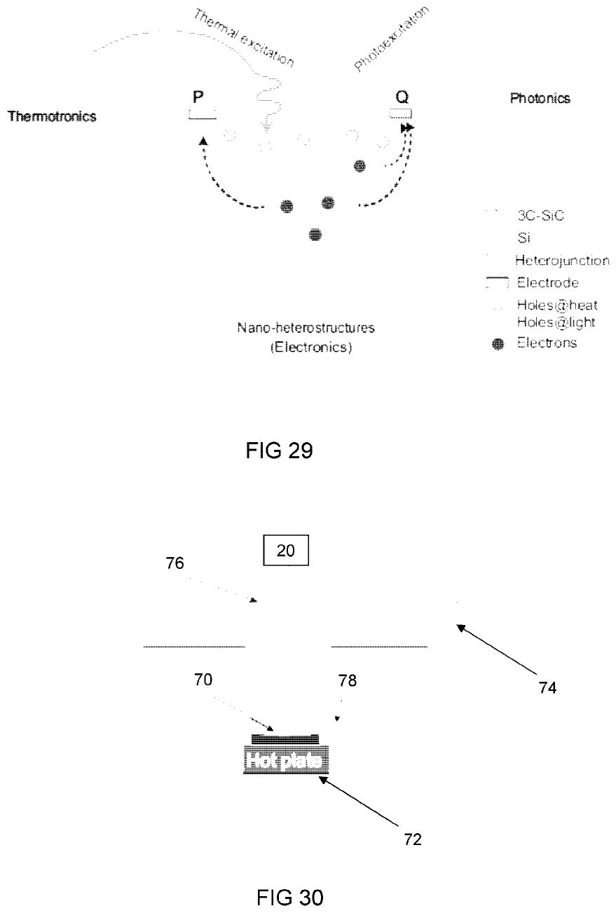

FIG. 29 is a schematic diagram illustrating the coupling of photonic excitation and thermal excitation of charge carriers in a SiC/Si semiconductor junction in the form of an optothermotronic sensing platform according to some embodiments of the present invention. Visible light illumination (not shown in FIG. 29) provides photons to excite charge carriers in the SiC/Si heterostructure and the silicon substrate while the SiC nanofilm is visible-blind. The uneven, inhomogeneous or asymmetric light illumination of the spaced apart electrodes P and Q induces a gradient of charge carrier concentration or a voltage gradient between the electrodes P and Q with a light intensity stronger at electrode Q and weaker at electrode P. This is referred to as the lateral photo-voltaic effect. Subsequently, temperature changes provide thermal energy to excite charge carriers from the acceptor level to the valance band. Coupling of photoexcitation and a tuning current in the SiC/Si platform enhances the transport properties of thermally excited charge carriers in the SiC nanofilm. Consequently, such platforms can be used for ultra-sensitive temperature sensors as described herein.

FIG. 30 shows an experimental setup for the characterisation of the thermoresistive effect in SiC nanofilms, i.e. resistance changes with temperature variation, and the optothermotronic effect in a sensing platform 70 or device in the form of a p+-SiC/p-Si heterojunction. The heterojunction comprises a SiC nanofilm 22 on a Si substrate 26 as described herein. In the thermoresistive measurements, a heat source 72 in the form of a hot plate was utilised in an enclosed chamber 74 to control the temperature of the sensing platform 70. The enclosed chamber 74 comprises an aperture 76 in an upper wall of the chamber. For characterising the optothermotronic effect, a light source 20 was placed outside the chamber 74 to provide nonuniform illumination of the sensing platform 70 through the aperture 76 to generate a lateral photovoltage in the SiC nanofilm 22 parallel to the p+-SiC/p-Si heterostructure. An electrical current I is applied to electrodes 14 on the SiC nanofilm 22 of the sensing platform 70 via wire bonds 78.

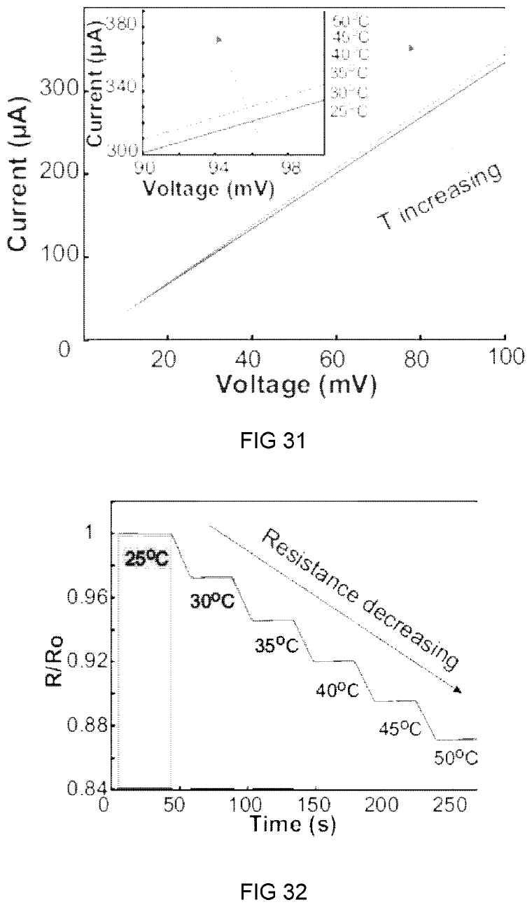

FIGS. 31 and 32 show measurement results for the thermoresistive effect of SiC nanofilms in dark conditions, i.e. with the light source 20 switched off. At a constant applied electrical current I, the measured voltage V decreased with increasing temperature, indicating a decrease of electrical resistance, as shown in FIG. 32. This suggests the dominance of the excited charge carriers compared to the carrier-lattice scattering effect in the p+-SiC nanofilm. At an applied current of I=340 μA, the measured voltage decreases from 100 mV to 88 mV, as shown in FIG. 31, corresponding to a decrease of above 10% of the electrical resistance of p+-SiC nanofilms, as shown in FIG. 32. When the temperature increases, the acceptors in SiC are excited by the thermal energy and contribute to an increase in the conductivity or a decrease in the electrical resistance. Based on the linear I-V characteristics shown in FIG. 31, the electrical resistance R is defined by Ohm law: R=V/I, and the relative resistance change is simply described in the form: ΔR/R₀=ΔV/V₀ where V₀ and R₀ are respectively the voltage and resistance measured at the reference temperature T₀. ΔV is the voltage change. In a narrow range of temperatures, the temperature coefficient of resistance (TCR) can be approximated as TCR=ΔR/R₀×1/ΔT, where ΔT=T−T₀ is the temperature change. The TCR value was found to be almost constant at approximately −0.5%/K when the temperature changed from 25° C. to 50° C. This TCR value is well established for the current thermoresistive temperature sensing technologies using commercialised resistive temperature detectors (RTD) sensors.

In the next section, the optothermotronic effect is demonstrated by coupling the photovoltaic effect and the thermoresistive effect via the generation and control of charge carriers in a sensing platform formed from a p+-SiC/p-Si semiconductor junction.

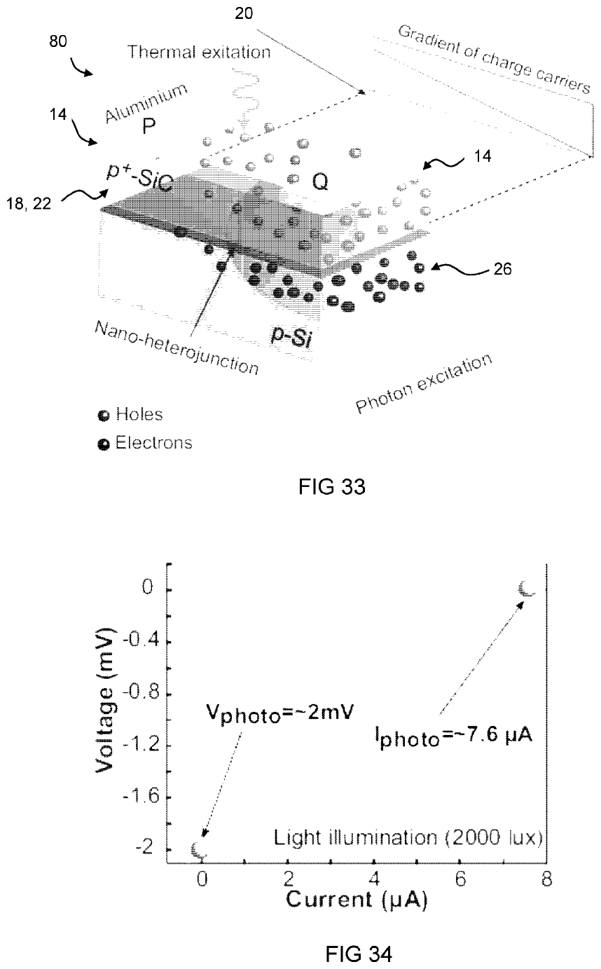

FIG. 33 is a perspective representation of a sensing platform 80 based on the coupling of photonic excitation and thermal excitation of charge carriers in a semiconductor junction according to some embodiments of the present invention. FIG. 33 illustrates optothermotronics in a p+-SiC/p-Si heterojunction under heat and visible light illumination from a light source 20. The nonuniform light illumination of spaced apart aluminium electrodes 14 (P, Q) introduces a gradient of charge carrier concentrations (i.e. holes) in the valance band of the SiC nanofilm 22. As such, the hole concentration increases from electrode P toward electrode Q owing to a high intensity of light illumination at electrode Q. Therefore, the quasi-Fermi level E_{FV,SiC} of charge carriers at electrode Q is closer to the valance band E_{V,SiC} compared to that at electrode P. This process results in an electric potential difference between electrodes P and Q. When the temperature increases, the acceptors in SiC are excited to the valance band of the SiC layer 22, which are modulated by the potential difference between electrodes P and Q.

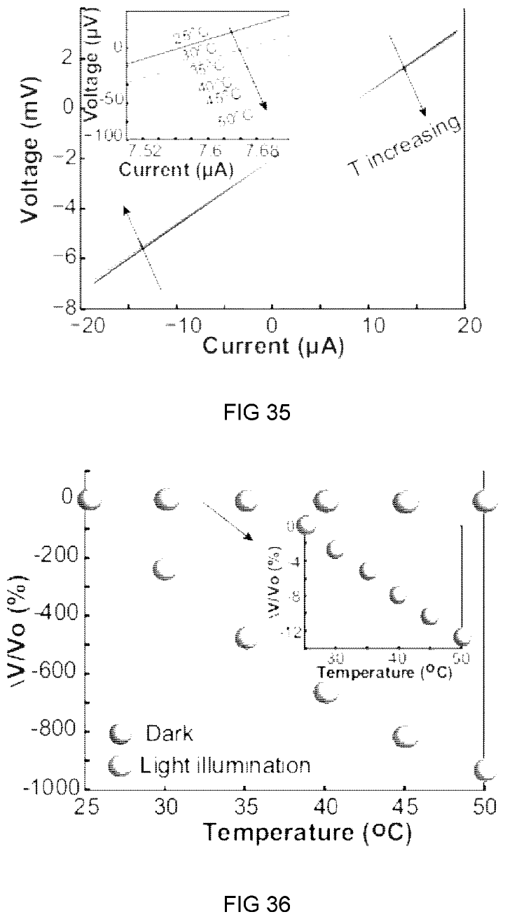

To validate this effect, the SiC nanofilm 22 is illuminated with visible light asymmetrically. With reference to FIG. 34, I-V measurements under a fixed light illumination of 2,000 lux were performed, indicating linear I-V characteristics. At a room temperature 25° C., the photovoltage Vₚₕₒₜₒ was about 2 mV and the generated photocurrent Iₚₕₒₜₒ was approximately 7.6 μA owing to the lateral photoeffect. FIG. 35 shows the full I-V measurement results under temperature variation. With reference to FIG. 35, close to the photocurrent of 7.6 μA, the measured voltage changed significantly with increasing temperature, as shown in the inset graph in FIG. 35. For quantitative evaluation of the optothermotronic effect, the temperature coefficient of resistance (TCR) was utilised which was determined as TCR=(ΔV/V₀)/(T−T₀), where I₀ and V₀ are the applied current and initial measured voltage, respectively.

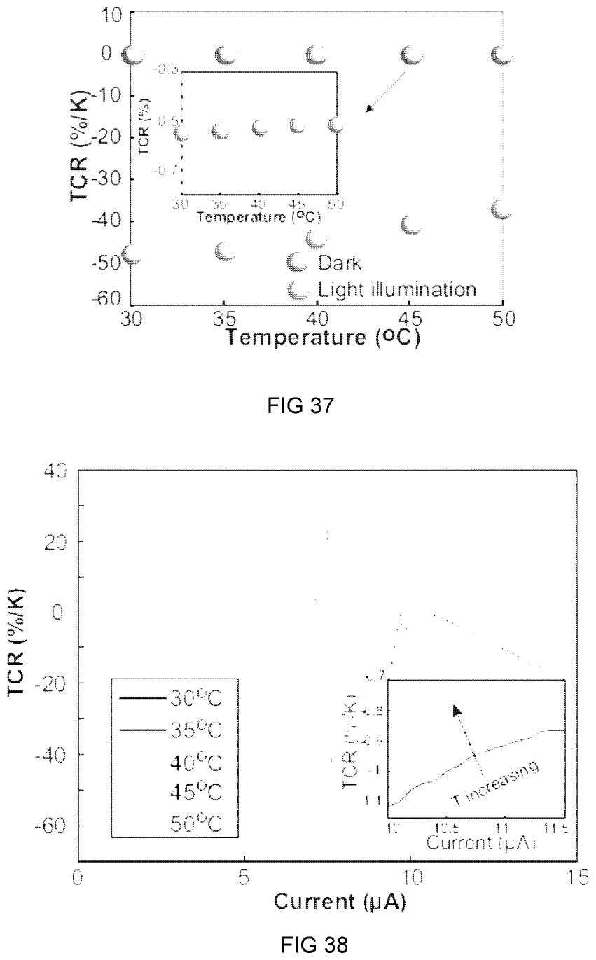

FIGS. 36 and 37 respectively show the relative voltage change and the change in TCR with temperature variation of the p+-SiC/p-Si heterojunction of sensing platform 80 under a light illumination of 2,000 lux compared with those measured under darkness. At 50° C., the relative voltage change under light conditions (ΔV=V₀)_{light} was measured with an increase of up to 1,000% when the temperature increases from the room temperature to 50° C. The increment of the voltage ratio between light and dark conditions (ΔV/V₀)/_{light}=(ΔV/Vₒ)_{dark} was clearly observed to be approximately 100 times at 50° C., as shown in FIG. 36. This enhancement reflects the significant contribution of the photovoltage gradient generated in the SiC nanofilm 22 under light illumination. With reference to FIG. 37, the TCR value of the SiC nanofilms 22 was relatively stable at −0.5%/K for a temperature range from 25 to 50° C. in dark conditions, while it increased approximately −50%/K under a light condition of 2,000 lux and an applied current of 7.6 μA. This increment indicates that the ultrasensitive temperature sensing effect of the p+-SiC/p-Si sensing platform 80 are achievable by manipulating the light conditions and the electric field/current. The results demonstrate the remarkable advance of the temperature sensing technology employing the lateral photoelectricity and thermal excitation of charge carriers in the SiC nanofilm 22 and nano-heterostructure.

The optothermotronic shows a tunable and controllable property. With reference to FIG. 38, in a range of applied currents either less than 5 μA or above 10 μA, the absolute TCR value was less than 1.5%/K, which is comparable with the stable TCR measured for the thermoresistive effect in darkness, as shown in the inset graph shown in FIG. 37. This is attributed to the dominance of the potential gradient generated by the photovoltaic effect compared with the opposite electric potential by injections (I<5 μA), which is opposite for I>10 μA. The thermally excited charge carriers, therefore, play an insignificant role to the temperature sensitivity.

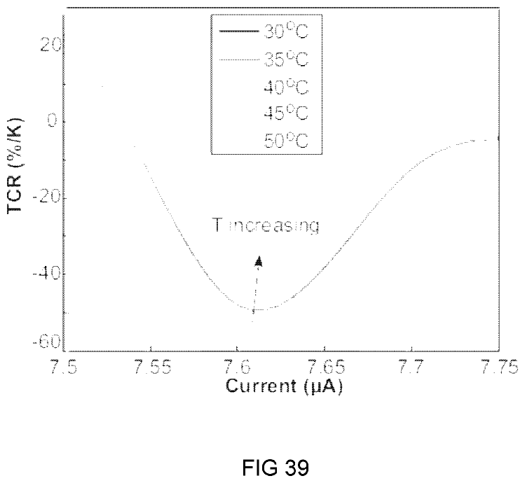

However, when the applied current provides a sufficient compensation between the potential of photogenerated charge carriers and the injected electric potential, a small measured voltage results in the current range of 5-10 μA. The charge carriers generated by thermal excitation create a large electric potential compared to the initial measured potential. Depending on the direction of the injected electrical potential, the thermally activated charge carriers can tune the TCR from positive to negative values. The highest negative TCR of up to −50%/K was observed, as shown in FIG. 39. At this photocurrent, the total potential difference V₀ is relatively small (less than 10 μV) due to the compensation of the photogenerated charge carrier potential and the injected electric potential. The charge carriers excited by the thermal energy will significantly increase this potential difference (e.g. output voltage) under the application of the injected current. Therefore, the ultra-high sensing performance was achieved for the p+-SiC/p-Si platform under visible light illumination. The performance of the optothermotronic sensing platform can be further improved by increasing the photovoltage Vₚₕₒₜₒ and photocurrent Iₚₕₒₜₒ.

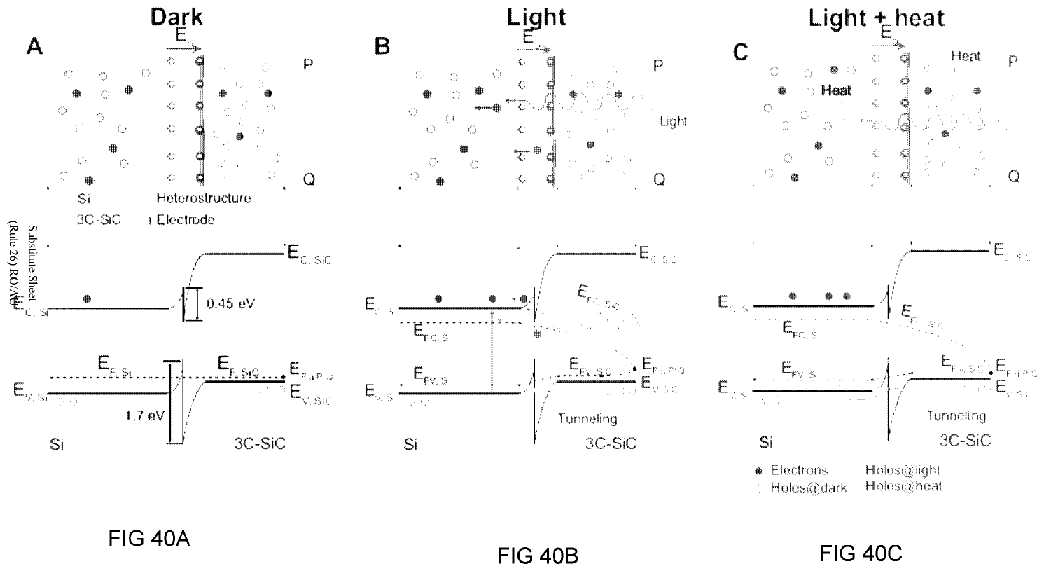

The enhancement of the optothermotronic devices depends upon the following parameters (i) absorption coefficient of photons; (ii) number of generated electron-hole pairs (EHP); and (iii) collection of charge carriers at the electrodes, which is tailored by the transfer process of charge carriers between the SiC and Si interface. FIG. 40A shows the charge distribution at the p+-SiC /p-Si interface and a respective band energy diagram. Owing to a high hole doping concentration of 5×10¹⁸ cm⁻³, holes from the p+-SiC diffuse to the p-Si substrate with a lower doping concentration of 10¹⁴ cm⁻³ and leave negative charge on the SiC side of the heterojunction. Electrons as minor carriers in the p-Si having a higher concentration therein move toward p+-SiC and generate positive charge on the Si side of the heterojunction, creating an electric field E₀. This electric field bends the valence band of p+-SiC upward with respect to that of p-Si. The formation of the band energy diagram in FIG. 40A is based on the conduction band offset of ΔE_{C}=0.45 eV and the valance band offset of ΔEV=1.7 eV between SiC and Si. With a large band gap of 2.3 eV, SiC is a visible-blind semiconductor with a low absorption coefficient.

With reference to FIG. 40B, under visible light illumination, the photogenerated electron-hole pairs (EHP) appear in the heterojunction and the silicon layer. The holes and electrons that do not combine, will contribute to the conductivity. Due to the non-equilibrium conditions under light illumination, the Fermi level E_{F} splits into two quasi-Fermi levels (e.g. E_{FC} for electrons, E_{FV} for holes), creating a chemical energy eV=E_{FC}−E_{FV}. Due to the large concentration of holes in p-type Si and SiC, the gradient of the Fermi energy for the valance band E_{FV} is smaller than the gradient of E_{FC}. Since p-Si initially has a lower hole concentration than p+-SiC, the photogenerated holes push the Fermi energy E_{FV,Si} more significantly toward the valance band E_{V,Si} compared to the shift of E_{FV,SiC} toward E_{V,SiC}. This leads to a potential difference between Si and SiC (e.g. E_{FV,Si}−E_{FV,SiC}) similar to that generated in solar cells. The built-in electric field E₀, creating a driving force, separates the EHP and drives the photogenerated holes in the heterostructure toward p+-SiC and photo-generated electrons toward p-Si. In the SiC layer, these holes flow toward to the right (e.g. at electrode P or Q) because the electrochemical potential decreases toward the right. Due to the strong recombination at the surface/electrode, the Fermi energies merge into a single Fermi energy (at P and Q).

With reference to FIG. 40C, when the temperature increases, the acceptors are excited by thermal energy and contribute the charge carriers in the valance band. It is hypothesized that thermally generated holes in p-Si can be driven toward p+-SiC by the build-in electric field E₀ and via a tunneling mechanism. This generates additional charge carriers and enhances the thermosensitivity of the p+-SiC nanofilms 22, which is discussed in detail as follows.

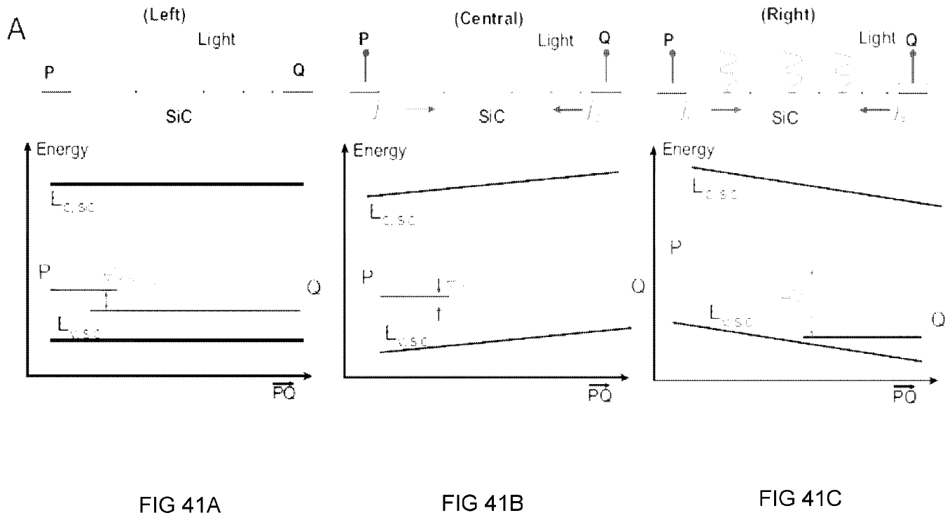

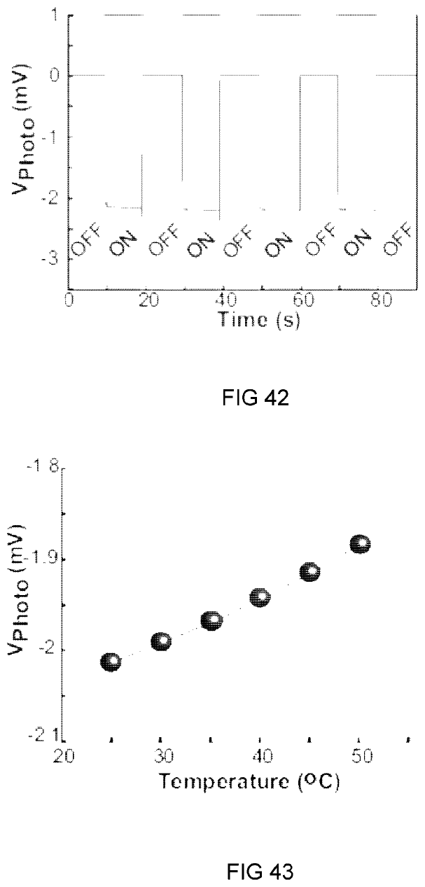

FIGS. 41A, 41B and 41C illustrate the modulation of optothermotronic potential of a p+-SiC nanofilm under illumination showing the photovoltage between two electrodes and a corresponding energy band diagram. Under nonuniform light illumination, the hole concentration at electrode Q is higher than that at P, forming an electric gradient or photovoltage Vₚₕₒₜₒ=E_{FV,SiC@P}−E_{FV,SiC@Q}, as shown in FIG. 41A. FIG. 42 shows this photovoltage Vₚₕₒₜₒ measured in real-time under ON/OFF states of a visible light illumination of 2,000 lux, showing the repeatability and reliability of the lateral photovoltage signal. The response time to the light illumination was estimated to be less than 50 ms. The value of Vₚₕₒₜₒ increases with increasing temperature at a rate of 0.2%/K, as shown in FIG. 43. This indicates that the chemical energy decreases with increasing temperature. It is speculated that the decrease of the energy barrier height between p-Si and p+-SiC is attributable to the reduction of the Fermi energy difference between p-Si and p+-SiC. The photovoltage induces a charge current which is defined by Fick's law of diffusion, j_{d}=−e×n×D×grad(n)/n, where e and n are the elementary charge and the charge concentration, respectively and D is the diffusion coefficient depending upon the carrier mobility.

By applying a bias current from electrodes P to Q (i.e. a negative potential placed at Q), the SiC band energy is bent upward from electrode P to electrodes Q. This bias current corresponds to an electric field E=−grad(φ), where φ is the electric potential which drives a field current j_{f} in the reverse direction of the diffusion current j_{d}, which is expressed as j_{f}=σ/e×grad(eφ), where σ is the conductivity of the charge carriers. Therefore, the field current compensates the diffusion current, resulting in a relatively small electric field in total, which was measured as V₀.

FIG. 41B shows this small potential difference V₀ induced between two electrodes P and Q at room temperature (25° C.). When the temperature increases, the thermal excitation of holes will significantly increase the conductivity of the charge carriers. Under a constant applied field current, the potential between electrodes P and Q is considerably bent downward, as shown in FIG. 41C.

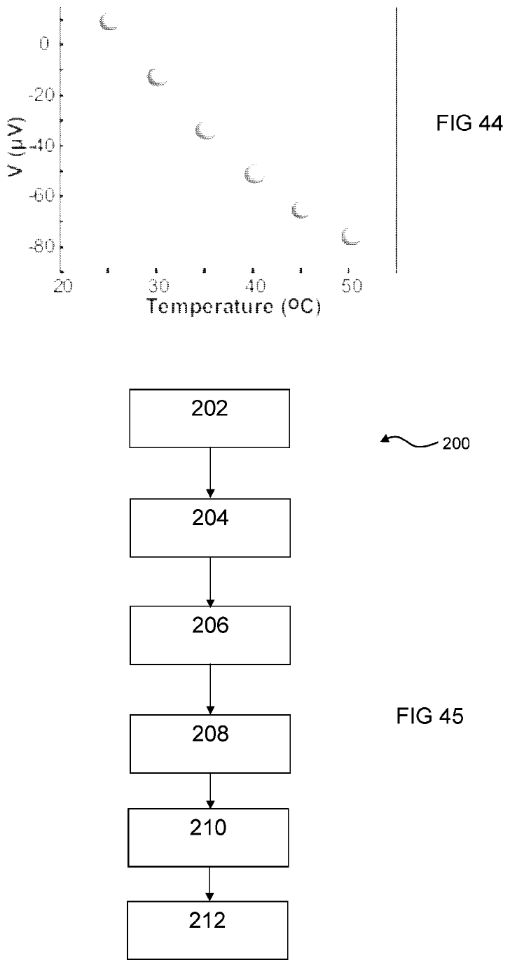

FIG. 44 shows the experimental results on the change of the measured voltage between electrodes P and Q with increasing temperatures. The measured voltage changed approximately 1,000% and its sign turned from positive to negative when the temperature increases from room temperature to 50° C. This giant change in measured voltage successfully demonstrates optothermotronics as an advanced temperature sensing technology for solid-state electronics and explains the operation of the temperature sensing platforms and temperature sensors according to embodiments of the present invention.

Hence, some embodiments of the present invention are directed to ultrasensitive thermal sensing platforms and sensors based on the optothermotronic effect in visible-blind semiconductor nanofilms, and in particular to p+-SiC nanofilms that formed a nano-heterostructure on a p-Si substrate. Optothermotronics employ the photon excitation in the p+-SiC/p-Si heterostructure to manipulate the thermal excitation of charge carriers in SiC nanofilms and modulate a giant temperature sensing effect. The optothermotronic effect is electrically controllable with the temperature sensitivity being tunable from negative TCR to positive TCR by compensating the photogenerated hole gradient and the electric potential. At a photovoltage of 2 mV and photocurrent of 7.6 μA, optothermotronics manipulated a giant TCR value of approximately −50%/K at room temperature. This temperature sensitivity is 100-fold larger than the thermoresistive sensitivity measured without photon excitation, which are at least two orders of magnitudes higher than the performance of current commercialised RTD sensors. In the thermal sensing platforms and sensors according to the present invention, the thermal excitation and transport of charge carriers is modulated by photon excitation to significantly enhance the performance of solid-state electronics beyond the state-of-the-art thermal sensing technologies.

With reference to FIGS. 21A and 21B, for the SiC nanofilms of the thermal sensing platforms and sensors according to some embodiments of the present invention, a hot-wall low pressure chemical vapour deposition (LPCVD) reactor was used to grow single crystalline cubic silicon carbide (3C—SiC) at 1,000° C. To provide Si and C atoms for the growth process, silane (99.999%) and acetylene (99.999%) were employed as precursors. A trimethylaluminium [(CH₃)₃Al, TMAI] precursor with an Al atomic concentration of above 10¹⁹ cm⁻³ was deployed to form p-type highly doped SiC materials in the in-situ growth process.

With reference to FIG. 21C, aluminium with a thickness of 300 nm was deposited on top of the SiC wafer by a sputtering process. With reference to FIG. 21D, a lithography process was performed with a 2 μm-thick positive photoresist layer spin-coated on the aluminium layer at a rotational speed of 4,000 rpm. The wafer was then soft baked at 105° C. for 90 s. The photoresist layer was patterned using ultraviolet (UV) light and a photoresist developer. With reference to FIG. 21E, a wet etching process was used to etch aluminium and form the electrodes. Finally, the photoresist layer was removed.

In an area of 5×5 μm², Atomic Force Microscopy (AFM) measurements indicated a root mean square (RMS) roughness of less than 20 nm. The thickness of the SiC films was determined to be 280 nm by Nanospec-based measurements with a nonuniformity across the as grown SiC wafer within ±1%. Hall measurements were performed to determine the doping concentration of carriers in the SiC films. Transmission Electron Microscope (TEM), Selected Area Electron Diffraction (SAED) and X-ray Diffraction (XRD) measurement techniques were employed to characterise the crystallinity of the SiC films grown on Si, as shown in the examples in FIGS. 15, 16 and 17. Temperature characterisation was performed using an enclosed Linkam chamber (HFS600E-PB4) and the light illumination at 2000 lux from a microscope. All electrical measurements including I-V characteristics were performed using a SourceMeter (Keithley 2450).

According to other aspects, and with reference to FIG. 45, embodiments of the present invention reside in a method 200 of creating a sensing platform in a semiconductor junction. At 202, the method 200 comprises coupling a pair of electrodes 14 to a surface 16 of an upper layer 18 of a semiconductor junction 12 in a spaced apart relationship. In particular, aluminium electrodes are deposited on top of a SiC wafer, as described herein.

At 204, the method 200 comprises illuminating a part of the surface 16 of the semiconductor junction 12 comprising at least part of one of the electrodes with visible light from a light source to create a lateral potential gradient between the pair of electrodes 14 through the photovoltaic effect in the semiconductor.

At 206, embodiments of the method 200 comprise detecting at least one parameter by the sensing platform is based on measuring a change in electrical resistance of the semiconductor material due to the piezoresistive effect and/or the thermoresistive effect

At 208, embodiments of the method 200 comprise applying an external potential difference between the pair of electrodes 14 to create a tuning current I to modulate the piezoresistive and/or the thermoresistive effects in the semiconductor junction 12.

At 210, embodiments of the method 200 comprise applying a mechanical stress or strain to the semiconductor junction to change the carrier mobility and electrical resistivity in the semiconductor material.

At 212, embodiments of the method 200 comprise applying thermal energy to the semiconductor junction to generate charge carriers and change the carrier mobility and electrical resistivity in the semiconductor material.

Hence, embodiments of the present invention provide sensing platforms and sensors which addresses, or at least ameliorate one or more of the aforementioned problems of prior art sensors. For example, sensing platforms and sensors according to embodiments of the present invention have ultra-high sensitivity and good linear response characteristics. That the sensing platforms and sensors can be embodied in a semiconductor junction with a proximal light source enable such sensing platforms and sensors to be miniaturised and adapted to a very wide variety of applications. In particular, embodiments of the present invention based on SiC/Si heterojunctions enable such sensing platforms and sensors to be used at high temperatures and in other harsh environments due to the excellent mechanical strength, chemical inertness, electrical stability and thermal durability of SiC.

In this specification, the terms “comprises”, “comprising” or similar terms are intended to mean a non-exclusive inclusion, such that an apparatus that comprises a list of elements does not include those elements solely, but may well include other elements not listed.

The reference to any prior art in this specification is not, and should not be taken as, an acknowledgement, or any form of suggestion that the prior art forms part of the common general knowledge.

Throughout the specification the aim has been to describe the present invention without limiting the invention to any one embodiment or specific collection of features. Persons skilled in the relevant art may realize variations from the specific embodiments that will nonetheless fall within the scope of the present invention.

1. A sensing platform comprising:
a semiconductor junction;
a pair of electrodes located on a surface of an upper layer of the semiconductor junction in a spaced apart relationship; and
a light source to illuminate a part of the surface of the semiconductor junction comprising at least part of one of the electrodes to create a lateral potential gradient between the pair of electrodes through the photovoltaic effect in the semiconductor;
wherein at least one parameter is detected based on measuring a change in electrical resistance of the semiconductor material due to the piezoresistive effect or the thermoresistive effect;
wherein the sensing platform is in the form of a pressure sensor having a diaphragm structure, wherein the semiconductor material comprises a recessed or thinned region to which force is applied and in which stress or strain is concentrated; or
wherein the sensing platform is in the form of a temperature sensor and a tuning current I is applied between the pair of electrodes to create an external potential difference to modulate the thermoresistive effect in the semiconductor junction and thus the temperature coefficient of resistance (TCR) and sensitivity of the temperature sensor.

2. The sensing platform of claim 1, wherein the semiconductor junction is in the form of a heterojunction comprising the upper layer on a substrate, wherein the upper layer is in the form of a nanofilm that allows light from the light source to pass through and the substrate absorbs the light and generates electron-hole pairs.

3. The sensing platform of claim 2, wherein the substrate is a small bandgap material, such as silicon or germanium.

4. The sensing platform of claim 1, wherein the semiconductor junction comprises a SiC/Si heterojunction or other materials and material combinations which possess a photovoltaic effect and a piezoresistive effect or thermoresistive effect, including semiconductor materials, such as GaAs, GaN, AlN and silicon.

5. The sensing platform of claim 1, wherein the semiconductor junction comprises a highly doped, p-type 3C—SiC nanofilm forming a heterojunction with a low-doped, p-type Si substrate.

6. The sensing platform of claim 1, wherein the pair of electrodes are metal electrodes, such as aluminium electrodes, or other materials that can form an Ohmic contact with the upper layer.

7. The sensing platform of claim 1, wherein the at least one parameter is one or more of the following: force; pressure; temperature.

8. The sensing platform of claim 1, wherein a force applied to the semiconductor material is detected based on a change in a resistance R of the semiconductor material due to the piezoresistive effect.

9. The sensing platform of claim 8, wherein the force is in the form of a mechanical stress or strain applied to the semiconductor junction which changes the carrier mobility and electrical resistivity in the semiconductor material.

10. The sensing platform of claim 1, wherein an external potential difference is applied between the pair of electrodes to create a tuning current Ito modulate the piezoresistive effect in the semiconductor junction.

11. The sensing platform of claim 1, wherein detection of the force applied to the semiconductor material is based on a fractional change in the resistance, ΔR/R₀, where ΔR is the resistance change of the semiconductor material due to the piezoresistive effect, R₀ is the initial resistance of the semiconductor material between the pair of electrodes and R₀=V₀/I, where V₀ is the voltage between the pair of electrodes and I is the tuning current.

12. The sensing platform of claim 1, wherein detection of temperature by the semiconductor material is based on a fractional change in the resistance, ΔR/R₀, where ΔR is the resistance change of the semiconductor material due to the thermoresistive effect, R₀ is the initial resistance of the semiconductor material between the pair of electrodes and R₀=V₀/I, where V₀ is the voltage between the pair of electrodes and I is the tuning current.

13. The sensing platform of claim 11, wherein, the tuning current I is optimised to minimise R₀ and therefore maximise the sensitivity of the sensor.

14. The sensing platform of claim 11, wherein the magnitude of the tuning current is controlled to be as close as possible to the magnitude of the photocurrent (the short-circuit current due to the photovoltaic effect) whilst maintaining stability.

15. A method of creating a sensing platform in a semiconductor junction comprising:
coupling a pair of electrodes to a surface of an upper layer of the semiconductor junction in a spaced apart relationship; and
illuminating a part of the surface of the semiconductor junction comprising at least part of one of the electrodes to create a lateral potential gradient between the pair of electrodes through the photovoltaic effect in the semiconductor;
wherein detecting at least one parameter by the sensing platform is based on measuring a change in electrical resistance of the semiconductor material due to the piezoresistive effect or the thermoresistive effect;
wherein the sensing platform is in the form of a pressure sensor having a diaphragm structure, and the method comprises applying a force to a recessed or thinned region of the semiconductor material in which stress or strain is concentrated; or
wherein the sensing platform is in the form of a temperature sensor and the method comprises applying a tuning current I between the pair of electrodes to create an external potential difference to modulate the thermoresistive effect in the semiconductor junction and thus the temperature coefficient of resistance (TCR) and sensitivity of the temperature sensor.

16. The method of claim 15, comprising applying an external potential difference between the pair of electrodes to create a tuning current to modulate the piezoresistive effect in the semiconductor junction.

17. The method of claim 15, comprising optimising the tuning current I to minimise R₀ and therefore maximise the sensitivity of the sensor, where R₀ is the initial resistance of the semiconductor material between the pair of electrodes and R₀=V₀/I, where V₀ is the voltage between the pair of electrodes.

18. The method of claim 15, comprising controlling the magnitude of the tuning current to be as close as possible to the magnitude of the photocurrent (the short-circuit current due to the photovoltaic effect) whilst maintaining stability.

19. The method of claim 15, comprising applying a mechanical stress or strain to the semiconductor junction to change the carrier mobility and electrical resistivity in the semiconductor material.

20. The method of claim 15, comprising applying thermal energy to the semiconductor junction to generate charge carriers and change the carrier mobility and electrical resistivity in the semiconductor material.
